(19) United States
(12) Patent Application Publication
(10) Pub. No.: US 2013/0032899 A1
(43) Pub. Date: Feb. 7, 2013

(54) SEMICONDUCTOR DEVICE

(71) Applicant: PANASONIC CORPORATION, Osaka (JP)

(72) Inventor: Yoshiya MORIYAMA, Toyama (JP)

(73) Assignee: PANASONIC CORPORATION, Osaka (JP)

(21) Appl. No.: 13/649,656

(22) Filed: Oct. 11, 2012

Related U.S. Application Data
(63) Continuation of application No. PCT/JP2011/002192, filed on Apr. 13, 2011.

(30) Foreign Application Priority Data
Nov. 22, 2010 (JP) 2010-259874

(51) Int. Cl. H01L 29/78

(52) U.S. Cl. 257/410; 257/E29.255

(57) ABSTRACT

An N-type MIS transistor includes an active region surrounded by an element isolation region in a semiconductor substrate, a gate insulating film formed on the active region and the element isolation region and having a high-k insulating film, and a gate electrode formed on the gate insulating film. An N-type impurity region is formed at least in a portion located below the gate insulating film out of a portion of the active region which contacts the element isolation region.

### CROSS-REFERENCE TO RELATED APPLICATION

This is a continuation of PCT International Application PCT/JP2011/002192 filed on Apr. 13, 2011, which claims priority to Japanese Patent Application No. 2010-259874 filed on Nov. 22, 2010. The disclosures of these applications including the specifications, the drawings, and the claims are hereby incorporated by reference in their entirety.

### BACKGROUND

The present disclosure relates to semiconductor devices and manufacturing methods thereof, and more particularly to semiconductor devices that have a metal-insulator-semiconductor field effect transistor (MISFET) including a gate insulating film having a high dielectric constant (high-k) insulating film including a threshold voltage adjustment metal (a metal for adjusting the threshold voltage), and manufacturing methods thereof.

In recent years, with reduction in power consumption and increase in speed of semiconductor integrated circuit devices, semiconductor devices have been proposed which include a MISFET (hereinafter referred to as the “MIS transistor”) using a high-k insulating film such as, e.g., a hafnium (Hf)-based film as a gate insulating film and using a metal-containing film or a stacked film of a metal-containing film and a silicon film as a gate electrode.

In order to reduce the threshold voltage of an N-type MIS transistor, a technique using as a gate insulating film a Hf-based film containing a threshold voltage adjustment metal such as, e.g., lanthanum (La) has been proposed (see, e.g., Japanese Patent Publication No. 2009-194352).

The reason why the threshold voltage of an N-type MIS transistor can be reduced by using as a gate insulating film a Hf-based film containing La is as follows. If La is contained in a Hf-based film, a dipole is formed in this Hf-based film. As a result, a flat band voltage is shifted in the negative direction, and an effective work function of the N-type MIS transistor is shifted toward a band edge, whereby the threshold voltage of the N-type MIS transistor can be reduced.

The term “effective work function” refers to a work function obtained from electrical characteristics of a MIS transistor, and is obtained from a work function as a physical property indicating the difference between a vacuum level and an energy level of a metal, and the influence of the level in an insulating film, etc.

The configuration of a conventional semiconductor device, specifically the configuration of an N-type MIS transistor that includes a gate insulating film having a high-k insulating film containing La, will be described below with reference to FIG. 35 and FIGS. 36A-36B. FIG. 35 is a plan view showing the configuration of the conventional semiconductor device. FIG. 36A is a cross-sectional view taken along the gate length direction, showing the configuration of the conventional semiconductor device. FIG. 36B is a cross-sectional view taken along the gate width direction, showing the configuration of the conventional semiconductor device. Specifically, FIGS. 36A-36B are cross-sectional views taken along lines XXXVIa-XXXVIa and XXXVIb-XXXVIb shown in FIG. 35, respectively.

As shown in FIG. 35 and FIGS. 36A-36B, the conventional semiconductor device includes an N-type MIS transistor nTr on a semiconductor substrate 100 having a P-type well region 102 formed therein. The N-type MIS transistor nTr includes a gate insulating film 103 formed on an active region 100a of the semiconductor substrate 100 which is surrounded by an element isolation region 101, a gate electrode 104 formed on the gate insulating film 103, N-type extension regions 106 (see particularly FIG. 36A) formed on both sides of the gate electrode 104 in the active region 100a, insulating sidewall spacers 107 formed on the side surfaces of the gate electrode 104, and N-type source/drain regions 109 (see particularly FIG. 36A) formed on both sides of the insulating sidewall spacers 107 in the active region 100a.

The gate insulating film 103 has a base film 103a contacting the active region 100a, and a high-k insulating film 103b formed on the underlying film 103a and containing La. The gate electrode 104 has a metal-containing film 104a contacting the gate insulating film 103, and a silicon film 104b formed on the metal-containing film 104a. Each of the insulating sidewall spacers 107 includes an inner sidewall spacer 107a having an L-shaped cross section, and an outer sidewall spacer 107b.

### SUMMARY

Through intensive studies, the inventor newly discovered the following problem of the conventional N-type MIS transistor that includes a gate insulating film having a high-k insulating film containing a threshold voltage adjustment metal (e.g., La etc.).

With miniaturization of semiconductor devices, the gate width is required to be reduced. However, in the case of the N-type MIS transistor that includes a gate insulating film having a high-k insulating film containing a threshold voltage adjustment metal, the threshold voltage increases as the gate width decreases. This problem will be described with reference to FIG. 37.

FIG. 37 is a graph showing the relation between the gate width (see “W” in FIG. 36B) and the threshold voltage. As shown by solid line in FIG. 37, in the conventional N-type MIS transistor, the magnitude Vthh of the threshold voltage corresponding to the gate width of Wh is higher than the magnitude Vthl of the threshold voltage corresponding to the gate width of W1 (W1>Wh, Vthh>Vthl). On the other hand, as shown by broken line in FIG. 37, the magnitude of the threshold voltage corresponding to the gate width of Wh is ideally the same as that corresponding to the gate width of W1. In other words, the threshold voltage ideally does not increase even if the gate width decreases. In the conventional N-type MIS transistor, however, as shown by solid line in FIG. 37, the threshold voltage increases as the gate width decreases.

In view of the above problem, it is an object of the present disclosure to prevent, in a semiconductor device that has an N-type MIS transistor including a gate insulating film having a high-k insulating film containing a threshold voltage adjustment metal, the threshold voltage of the N-type MIS transistor from increasing even if the gate width decreases.

In order to achieve the above object, the inventor found through intensive studies that the reason why the threshold voltage increases as the gate width decreases in a semiconductor device having the conventional N-type MIS transistor is as follows.

The gate insulating film having the high-k insulating film is formed on the active region and the element isolation region in the gate width direction. Thus, the high-k insulating film containing the threshold voltage adjustment metal such as, e.g., lanthanum (La) reacts with oxygen (O) that is diffused from an insulating film (e.g., a silicon oxide film) forming the element isolation region. Accordingly, a part of the gate insulating film on the active region, which is located close to the element isolation region, is negatively charged, and holes are induced in the surface of the active region located immediately below the negatively charged gate insulating film. As a result, the threshold voltage is locally increased.

The present disclosure was developed based on the above finding. Specifically, a semiconductor device according to the present disclosure is a semiconductor device including an N-type MIS transistor, wherein the N-type MIS transistor includes an active region surrounded by an element isolation region in a semiconductor substrate, a gate insulating film formed on the active region and the element isolation region and having a high-k insulating film, a gate electrode formed on the gate insulating film, N-type source/drain regions formed on both sides of the gate electrode in the active region, and an N-type impurity region formed at least in a portion located below the gate insulating film out of a portion of the active region which contacts the element isolation region. As used herein, the term “high-k insulating film” refers to an insulating film having a relative dielectric constant of 8 or more (i.e., having a higher relative dielectric constant than SiN).

The semiconductor device according to the present disclosure has the following advantage. The N-type impurity region is formed in the portion of the active region which is located below the gate insulating film and which contacts the element isolation region. Thus, even if a part of the gate insulating film on the active region, which is located close to the element isolation region, is negatively charged due to the reaction between oxygen diffused from the element isolation region and the high-k insulating film, and holes are induced in a surface of the active region, the induced holes are neutralized due to the N-type impurity region. That is, since the N-type impurity region, i.e., the impurity region including electrons as majority carriers, is formed in a part of the active region where the induced holes are present, the holes induced in the active region can be neutralized by the electrons as majority carriers included in the N-type impurity region. This can prevent the threshold voltage from being locally increased due to the holes induced in the active region. Thus, the threshold voltage of the N-type MIS transistor can be prevented from being increased even if the gate width is reduced with miniaturization of semiconductor devices.

In the semiconductor device according to the present disclosure, the N-type impurity region may be formed at both ends in a gate width direction of the active region, or may be formed so as to surround the active region.

In the semiconductor device according to the present disclosure, the element isolation region may have a two-layer structure. In this case, a lower surface of the N-type impurity region may be located at a same depth as or a greater depth than a lower surface of an upper layer portion of the element isolation region.

In the semiconductor device according to the present disclosure, the element isolation region may be formed by a single insulating film.

In the semiconductor device according to the present disclosure, the N-type impurity region may be formed to extend to a shallower depth than the N-type source/drain regions, or may be formed to extend to a greater depth than the N-type source/drain regions.

In the semiconductor device according to the present disclosure, the N-type impurity region may have an impurity concentration in a range of 1×10¹⁸ atoms/cm³ to 1×10²⁰ atoms/cm³, both inclusive. In this case, the above advantage can be reliably obtained.

In the semiconductor device according to the present disclosure, the N-type impurity region may have a length in a range of 10 nm to 40 nm, both inclusive, in a gate width direction. In this case, the above advantage can be reliably obtained. Moreover, since the N-type impurity region is formed only in a part of the active region where the induced holes are present, the influence of the N-type impurity region on transistor characteristics can be minimized.

In the semiconductor device according to the present disclosure, the above advantage can be reliably obtained if the N-type impurity region may have a depth in a range of 20 nm to 100 nm, both inclusive, from a surface of the semiconductor substrate. Moreover, since the N-type impurity region is formed only near the surface of the active region, the active regions adjoining each other with the element isolation region interposed therebetween can be prevented from being electrically connected through the N-type impurity region.

In the semiconductor device according to the present disclosure, the above advantage becomes more significant as compared to the conventional semiconductor device, when the active region has a length of 500 nm or less in a gate width direction.

In the semiconductor device according to the present disclosure, the N-type impurity region may contain arsenic or antimony.

In the semiconductor device according to the present disclosure, the gate insulating film may further have a base film formed below the high-k insulating film.

In the semiconductor device according to the present disclosure, the high-k insulating film may contain a threshold voltage adjustment metal. In this case, the threshold voltage adjustment metal may be lanthanum.

In the semiconductor device according to the present disclosure, the gate electrode may have a metal-containing film formed on the gate insulating film, and a silicon film formed on the metal-containing film.

A manufacturing method of a semiconductor device according to the present disclosure is a manufacturing method of a semiconductor device that includes an N-type MIS transistor having a gate electrode formed on an active region of a semiconductor substrate with a gate insulating film interposed therebetween. The method includes the steps of: (a) forming a hard mask on the active region; (b) obliquely implanting N-type impurities into the semiconductor substrate having the hard mask formed thereon; (c) after forming an insulating film on a region of the semiconductor substrate where the hard mask is not formed, removing the hard mask and a part of the insulating film to form an element isolation region surrounding the active region; (d) forming on the active region and the element isolation region a film for a gate insulating film, which has a high-k insulating film; (e) forming a film for a gate electrode on the film for the gate insulating film; and (f) patterning the film for the gate electrode and the film for the gate insulating film to form the gate electrode on the active region and the element isolation region with the gate insulating film interposed therebetween.

The manufacturing method of the semiconductor device according to the present disclosure has the following advantage. An N-type impurity region is formed by implanting the N-type impurities into a portion of the active region which contacts the element isolation region. Thus, even if a part of the gate insulating film on the active region, which is located close to the element isolation region, is negatively charged due to the reaction between oxygen diffused from the element isolation region and the high-k insulating film, and holes are induced in a surface of the active region, the induced holes are neutralized due to the N-type impurity region. That is, since the N-type impurity region, i.e., the impurity region including electrons as majority carriers, is formed in a part of the active region where the induced holes are present, the holes induced in the active region can be neutralized by the electrons as majority carriers included in the N-type impurity region. This can prevent the threshold voltage from being locally increased due to the holes induced in the active region. Thus, the threshold voltage of the N-type MIS transistor can be prevented from being increased even if the gate width is reduced with miniaturization of semiconductor devices.

The manufacturing method of the semiconductor device according to the present disclosure may further include the step of (g), between the steps (a) and (b), forming a trench by removing a region of an upper part of the semiconductor substrate where the hard mask is not formed, and then forming a first buried insulating film so that the trench is buried to an intermediate depth thereof, wherein in the step (b), the N-type impurity region may be formed in a portion of the active region which is exposed from a region of the trench located above the first buried insulating film, and in the step (c), after forming a second buried insulating film on the first buried insulating film so as to bury the trench, the hard mask and a part of the second buried insulating film may be removed to form the element isolation region formed by the first buried insulating film and the second buried insulating film. In this case, the N-type impurity region is formed in the portion of the active region which is exposed from the region of the trench located above the first buried insulating film. Thus, the N-type impurity region can be formed only near the surface of the active region. This can prevent the active regions adjoining each other with the element isolation region interposed therebetween from being electrically connected through the N-type impurity region. In this case, if the distance from a surface of the semiconductor substrate to a surface of the first buried insulating film is in a range of 20 nm to 100 nm, both inclusive, in the step (g), an increase in threshold voltage of the N-type MIS transistor can be prevented, and also the active regions adjoining each other with the element isolation region interposed therebetween can be reliably prevented from being electrically connected through the N-type impurity region.

In the manufacturing method of the semiconductor device according to the present disclosure, in the step (b), an N-type impurity region may be formed in a part of a surface portion of the active region, which adjoins the region where the hard mask is not formed. The method may further include the step of (h), between the steps (b) and (c), forming a trench by removing the region of the upper part of the semiconductor substrate where the hard mask is not formed. In the step (c), after forming the insulating film so as to bury the trench, the hard mask and the part of the buried insulating film may be removed to form the element isolation region. In this case, the oblique implantation of the N-type impurities is performed before formation of the trench for forming the element isolation region. Thus, the N-type impurity region can be formed only near the surface of the active region. This can prevent the active regions adjoining each other with the element isolation region interposed therebetween from being electrically connected through the N-type impurity region.

The manufacturing method of the semiconductor device according to the present disclosure may further include the step of (i), between the steps (a) and (b), forming a first trench by removing the region of the surface portion of the semiconductor substrate where the hard mask is not formed. In the step (b), the N-type impurity region may be formed in a portion of the active region which serves as sidewall portions of the first trench. The manufacturing method of the semiconductor device according to the present disclosure may further include the step of (j), between the steps (b) and (c), forming a second trench by removing a region of the upper part of the semiconductor substrate which is located under the first trench. In the step (c), after forming the insulating film so as to bury the second trench, the hard mask and the part of the insulating film may be removed to form the element isolation region. In this case, the N-type impurity region is formed in the portion of the active region which serves as the sidewall portions of the shallow first trench. Thus, the N-type impurity region can be formed only near the surface of the active region. This can prevent the active regions adjoining each other with the element isolation region interposed therebetween from being electrically connected through the N-type impurity region. In this case, if the distance from the surface of the semiconductor substrate to a bottom surface of the first trench is in a range of 20 nm to 100 nm, both inclusive, in the step (i), an increase in threshold voltage of the N-type MIS transistor can be prevented, and also the active regions adjoining each other with the element isolation region interposed therebetween can be reliably prevented from being electrically connected through the N-type impurity region.

The manufacturing method of the semiconductor device according to the present disclosure may further include the step of (k), between the steps (a) and (b), forming a trench by removing the region of the upper part of the semiconductor substrate where the hard mask is not formed. In the step (b), the N-type impurity region may be formed at least in an upper part of the portion of the active region which serves as the sidewall portions of the first trench.

In the manufacturing method of the semiconductor device according to the present disclosure, the N-type impurities may be arsenic or antimony in the step (b). In this case, the implanted impurities are hardly diffused in a heat treatment that is performed after the oblique implantation of the N-type impurities, whereby unintended expansion of the N-type impurity region can be prevented.

In the manufacturing method of the semiconductor device according to the present disclosure, in the step (b), the oblique implantation of the N-type impurities may be performed from two directions of a gate length direction and two directions of a gate width direction. This increases flexibility of transistor layout in the case where a plurality of transistors are provided on the semiconductor substrate.

In the manufacturing method of the semiconductor device according to the present disclosure, in the step (b), the oblique implantation of the N-type impurities may be performed from the two directions of the gate width direction. This can improve throughput and also can prevent an increase in threshold voltage of the N-type MIS transistor. In this case, in the step (b), the oblique implantation of the N-type impurities may be performed by using a resist mask having an opening in a region where the gate electrode is to be formed. This can minimize the range where the N-type impurity region should be formed, and thus can minimize the influence of the N-type impurity region on transistor characteristics.

As described above, the present disclosure has an advantage in that an increase in threshold voltage of the N-type MIS transistor can be prevented even if the gate width is reduced with miniaturization of semiconductor devices. Thus, the present disclosure is useful for semiconductor devices that have an N-type MIS transistor including a gate insulating film having a high-k insulating film containing a threshold voltage adjustment metal, and manufacturing methods thereof.

### BRIEF DESCRIPTION OF THE DRAWINGS

FIG. 1A is a cross-sectional view taken along the gate width direction, showing the configuration of a semiconductor device according to a first examination example, and FIG. 1B is a cross-sectional view taken along the gate width direction, showing the configuration of a semiconductor device according to a second examination example t.

FIG. 2 is a diagram showing the relation between the gate width and the threshold voltage in the semiconductor devices according to the first and second examination examples.

FIG. 3 is a plan view showing the configuration of a semiconductor device according to a first embodiment.

FIGS. 4A-4B are cross-sectional views taken along lines IVa-IVa and IVb-IVb in FIG. 3, respectively.

FIGS. 5A-5B are cross-sectional views showing a step of a manufacturing method of the semiconductor device according to the first embodiment.

FIGS. 6A-6B are cross-sectional views showing a step of the manufacturing method of the semiconductor device according to the first embodiment.

FIGS. 7A-7B are cross-sectional views showing a step of the manufacturing method of the semiconductor device according to the first embodiment.

FIGS. 8A-8B are cross-sectional views showing a step of the manufacturing method of the semiconductor device according to the first embodiment.

FIGS. 9A-9B are cross-sectional views showing a step of the manufacturing method of the semiconductor device according to the first embodiment.

FIGS. 10A-10B are cross-sectional views showing a step of the manufacturing method of the semiconductor device according to the first embodiment.

FIGS. 11A-11B are cross-sectional views showing a step of the manufacturing method of the semiconductor device according to the first embodiment.

FIGS. 12A-12B are cross-sectional views showing a step of the manufacturing method of the semiconductor device according to the first embodiment.

FIGS. 13A-13B are cross-sectional views showing a step of the manufacturing method of the semiconductor device according to the first embodiment.

FIGS. 14A-14B are cross-sectional views showing a step of the manufacturing method of the semiconductor device according to the first embodiment.

FIGS. 15A-15B are cross-sectional views showing a step of the manufacturing method of the semiconductor device according to the first embodiment.

FIGS. 16A-16B are cross-sectional views showing a step of the manufacturing method of the semiconductor device according to the first embodiment.

FIG. 17 is a plan view showing a variation of the configuration of the semiconductor device according to the first embodiment.

FIGS. 18A-18B are cross-sectional views showing a variation of a step of the manufacturing method of the semiconductor device according to the first embodiment.

FIG. 19 is a plan view showing a variation of the configuration of the semiconductor device according to the first embodiment.

FIG. 20 is a plan view showing the configuration of a semiconductor device according to a first modification of the first embodiment.

FIGS. 21A-21B are cross-sectional views taken along lines XXIa-XXIa and XXIb-XXIb in FIG. 20, respectively.

FIGS. 22A-22B are cross-sectional views showing a step of a manufacturing method of the semiconductor device according to the first modification of the first embodiment.

FIGS. 23A-23B are cross-sectional views showing a step of the manufacturing method of the semiconductor device according to the first modification of the first embodiment.

FIGS. 24A-24B are cross-sectional views showing a step of the manufacturing method of the semiconductor device according to the first modification of the first embodiment.

FIGS. 25A-25B are cross-sectional views showing a step of the manufacturing method of the semiconductor device according to the first modification of the first embodiment.

FIGS. 26A-26B are cross-sectional views showing a step of the manufacturing method of the semiconductor device according to the first modification of the first embodiment.

FIG. 27 is a plan view showing the configuration of a semiconductor device according to a second modification of the first embodiment.

FIGS. 28A-28B are cross-sectional views taken along lines XXVIIIa-XXVIIIa and XXVIIIb-XXVIIIb in FIG. 27, respectively.

FIGS. 29A-29B are cross-sectional views showing a step of a manufacturing method of the semiconductor device according to the second modification of the first embodiment.

FIGS. 30A-30B are cross-sectional views showing a step of the manufacturing method of the semiconductor device according to the second modification of the first embodiment.

FIGS. 31A-13B are cross-sectional views showing a step of the manufacturing method of the semiconductor device according to the second modification of the first embodiment.

FIG. 32 is a plan view showing the configuration of a semiconductor device according to a third modification of the first embodiment.

FIGS. 33A-33B are cross-sectional views taken along lines XXXIIIa-XXXIIIa and XXXIIIb-XXXIIIb in FIG. 32, respectively.

FIGS. 34A-34B are cross-sectional views showing a step of a manufacturing method of the semiconductor device according to the third modification of the first embodiment.

FIG. 35 is a plan view showing the configuration of a conventional semiconductor device.

FIGS. 36A-36B are cross-sectional views taken along lines XXXVIa-XXXVIa and XXXVIb-XXXVIb in FIG. 35, respectively.

FIG. 37 is a diagram showing the relation between the gate width and the threshold voltage in the conventional semiconductor device.

### DETAILED DESCRIPTION

(Mechanism of Present Disclosure)

As described above, the inventor found through intensive studies that the reason why the threshold voltage increases as the gate width decreases in the semiconductor device having the conventional N-type MIS transistor is as follows.

The gate insulating film having the high-k insulating film is formed on the active region and the element isolation region in the gate width direction. Thus, the high-k insulating film containing the threshold voltage adjustment metal such as, e.g., lanthanum (La) reacts with oxygen (O) that is diffused from an insulating film (e.g., a silicon oxide film) forming the element isolation region. Accordingly, a part of the gate insulating film on the active region, which is located close to the element isolation region, is negatively charged, and holes are induced in the surface of the active region located immediately below the negatively charged gate insulating film. As a result, the threshold voltage is locally increased.

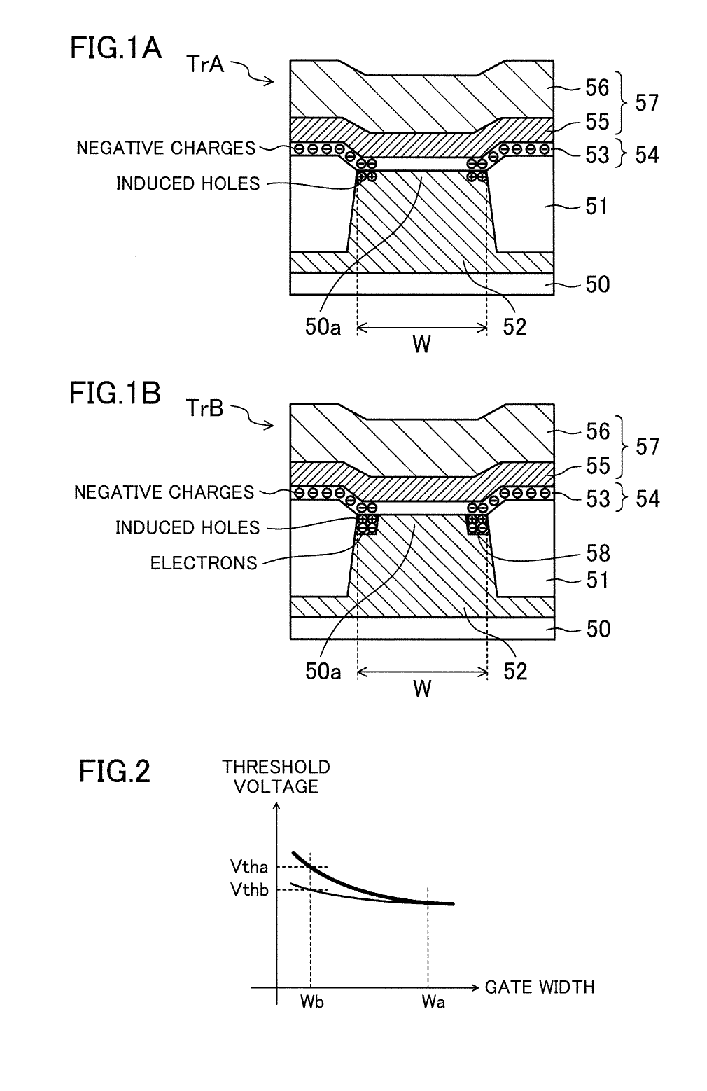

The problem discovered by the inventor and the finding of the inventor about the problem will be described in detail below with reference to FIGS. 1A-1B and FIG. 2. FIG. 1A is a cross-sectional view taken along the gate width direction, showing the configuration of a semiconductor device according to a first examination example. FIG. 1B is a cross-sectional view taken along the gate width direction, showing the configuration of a semiconductor device according to a second examination example. FIG. 2 is a graph showing the relation between the gate width and the threshold voltage in the semiconductor devices according to the first and second examination examples.

As shown in FIG. 1A, the semiconductor device according to the first examination example includes an N-type MIS transistor TrA on a semiconductor substrate 50 having a P-type well region 52 formed therein. As shown in FIG. 1B, the semiconductor device according to the second examination example includes an N-type MIS transistor TrB on a semiconductor substrate 50 having a P-type well region 52 formed therein.

As shown in FIGS. 1A-1B, each of the N-type MIS transistors TrA, TrB includes a gate insulating film 54 formed on an active region 50a of the semiconductor substrate 50 which is surrounded by an element isolation region 51, and a gate electrode 57 formed on the gate insulating film 54. The gate insulating film 54 has a high-k insulating film 53 containing La. The gate electrode 57 has a metal-containing film 55 and a silicon film 56 formed on the metal-containing film 55.

In the N-type MIS transistor TrB shown in FIG. 1B, an N-type impurity region 58 is locally provided in a part of a surface portion of the active region 50a which is located below the gate insulating film 54 and which adjoins the element isolation region 51.

FIG. 2 shows the measurement result (thick line in FIG. 2) of the threshold voltage of the N-type MIS transistor TrA of FIG. 1A measured while changing the gate width W (see FIG. 1A), and the measurement result (thin line in FIG. 2) of the threshold voltage of the N-type MIS transistor TrB of FIG. 1B measured while changing the gate width W (see FIG. 1B).

As shown in FIG. 2, when the gate width W is Wa, namely when the gate width W is relatively great, the magnitude of the threshold voltage is the same regardless of whether the N-type impurity region 58 is provided in the portion of the active region 50a which adjoins the element isolation region 51.

However, as shown in FIG. 2, when the gate width W is Wb, namely when the gate width W is relatively narrow, the magnitude Vtha of the threshold voltage of the N-type MIS transistor TrA (FIG. 1A) having no N-type impurity region 58 in the portions of the active region 50a which adjoin the element isolation region 51 is higher than the magnitude Vthb of the threshold voltage of the N-type MIS transistor TrB (FIG. 1B) having the n-type impurity region 58 in those portions (Vtha>Vthb).

This phenomenon in which the threshold voltage increases as the gate width decreases in the N-type MIS transistor TrA of FIG. 1A (i.e., the conventional N-type MIS transistor) occurs for the following reason.

As shown in FIGS. 1A-1B, portions of the gate insulating film 54 which are located on the element isolation region 51 and portions of the gate insulating film 54 which are located on the active region 50a adjoining the element isolation region 51 are locally negatively charged. This occurs for the following reason. The high-k insulating film 53 containing La forms a dipole and is electrically positively charged. However, a heat treatment that is performed after formation of the high-k insulating film 53 containing La diffuses oxygen (O) into the high-k insulating film 53 (in particular, a part of the high-k insulating film 53 which is in contact with the active region 50a). Reaction between La contained in the high-k insulating film 53 and O causes neutralization of the dipole. Namely, a part of the high-k insulating film 53 where O has been diffused is negatively charged, as compared to a part of the high-k insulating film 53 where O has not been diffused (that is, a part of the high-k insulating film 53 which is located sufficiently away from the element isolation region 51). As a result, holes are induced in the surface of the active region 50a immediately below the locally negatively charged gate insulating film 54. Thus, the threshold voltage of the transistor is locally increased.

An insulating film (e.g., a silicon oxide film) forming the element isolation region 51, etc. is mainly a diffusion source of O that reacts with La contained in the high-k insulating film 53. The heat treatment that diffuses O is, e.g., a heat treatment that activates N-type impurities contained in N-type source/drain implantation regions to form N-type source/drain regions, etc.

In the surface of the active region 50a, holes are induced in a region having a constant dimension in the gate width direction regardless of the gate width W of the N-type MIS transistor. Thus, the influence of the region (the region in the gate width direction) in the surface of the active region 50a where holes are induced on the transistor becomes more significant as the gate width W of the N-type MIS transistor decreases. Thus, the threshold voltage increases as the gate width W decreases.

On the other hand, as shown in FIG. 1B, in the case where the N-type impurity region 58 is provided in the portion of the active region 50a which adjoins the element isolation region 51, holes locally induced in the surface of the active region 50a can be neutralized by electrons included in the N-type impurity region 58 as majority carriers. Thus, providing the N-type impurity region 58 in the portion of the active region 50a which adjoins the element isolation region 51 can prevent the threshold voltage of the transistor from increasing locally.

As described above, through intensive studies, the inventor found that, in order to prevent the threshold voltage from increasing as the gate width decreases in the semiconductor device that has the N-type MIS transistor including the gate insulating film having the high-k insulating film containing the threshold voltage adjustment metal, it is effective to increase the electron density in the surface portion of the active region adjoining the element isolation region at least below the gate insulating film. The following embodiments are based on this finding.

### First Embodiment

A semiconductor device according to a first embodiment of the present disclosure will be described below with reference to the drawings.

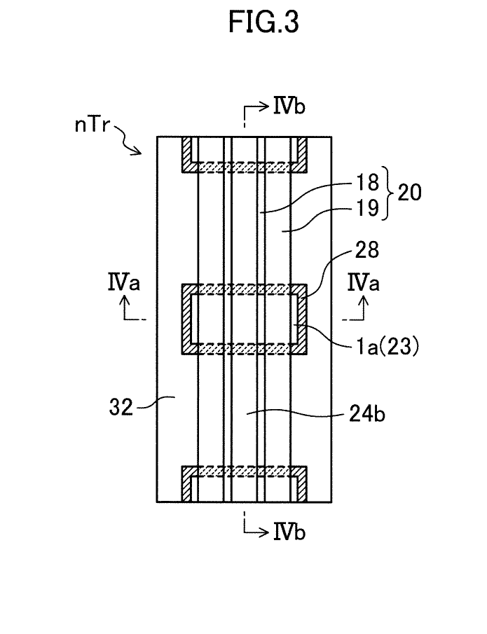

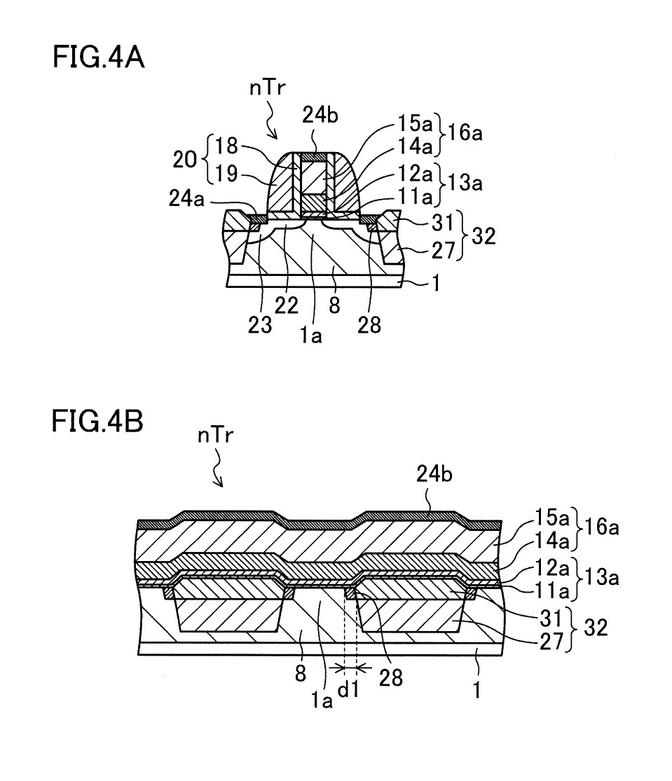

FIG. 3 is a plan view showing the configuration of the semiconductor device according to the present embodiment. FIG. 4A is a cross-sectional view taken along the gate length direction, showing the configuration of the semiconductor device according to the present embodiment. FIG. 4B is a cross-sectional view taken along the gate width direction, showing the configuration of the semiconductor device according to the present embodiment. Specifically, FIGS. 4A-4B are cross-sectional views taken along lines IVa-IVa and IVb-IVb in FIG. 3, respectively. A silicide film formed on active regions (source/drain regions) is not shown in FIG. 3.

As shown in FIG. 3 and FIGS. 4A-4B, the semiconductor device according to the present embodiment includes an N-type MIS transistor nTr on a semiconductor substrate 1 having a P-type well region 8 formed therein. For example, the N-type MIS transistor nTr has a gate length of about 32 nm and a gate width of about 150 nm.

The N-type MIS transistor nTr includes: an active region 1a of the semiconductor substrate 1 which is surrounded by an element isolation region 32; a gate insulating film 13a formed on the active region 1a and the element isolation region 32; a gate electrode 16a formed on the gate insulating film 13a; N-type extension regions 22 (see particularly FIG. 4A) formed on both sides of the gate electrode 16a in the active region 1a; insulating sidewall spacers 20 formed on the side surfaces of the gate electrode 16a; N-type source/drain regions 23 (see particularly FIG. 4A) formed on both sides of the insulating sidewall spacers 20 in the active region 1a; first silicide films 24a (see particularly FIG. 4A) formed on the N-type source/drain regions 23; and a second silicide film 24b formed on the gate electrode 16a.

The gate insulating film 13a has a base film (e.g., an interface layer comprised of a silicon oxide film) 11a contacting the active region 1a, and a high-k insulating film 12a formed on the base film 11a and containing a threshold voltage adjustment metal (e.g., La). The gate electrode 16a has a metal-containing film 14a formed on the gate insulating film 13a, and a silicon film 15a formed on the metal-containing film 14a. Each of the insulating sidewall spacers 20 has an inner sidewall spacer 18 having an L-shaped cross section, and an outer sidewall spacer 19. The element isolation region 32 has a two-layer stacked structure of a first buried insulating film 27 as a lower layer and a second buried insulating film 31 as an upper layer.

The present embodiment is characterized in that an N-type impurity region 28 is formed in a part (including a portion immediately below the gate insulating film 13a) of a surface portion of the active region 1a which adjoins the element isolation region 32. As shown in FIG. 3, the N-type impurity region 28 is formed so as to surround the active region 1a. In other words, the N-type impurity region 28 is formed at both ends in the gate length direction of the active region 1a and at both ends in the gate width direction of the active region 1a.

The N-type impurity region 28 contains, e.g., arsenic or antimony. The impurity concentration n1 of the N-type impurity region 28 is in the range of, e.g., about 1×10¹⁸ atoms/cm³ to about 1×10²⁰ atoms/cm³, both inclusive (1×10¹⁸ ≦n1≦1×10²⁰). The width d1 in the gate width direction of the N-type impurity region 28 is in the range of, e.g., about 10 nm to about 40 nm, both inclusive.

The N-type impurity region 28 extends to a shallower depth in the semiconductor substrate 1 than the N-type source/drain regions 23. The lower surface of the N-type impurity region 28 is located at the same depth as or a greater depth in the semiconductor substrate 1 than the lower surface of the upper layer portion (the second buried insulating film 31) of the element isolation region 32.

The P-type well region 8 has an impurity concentration of, e.g., about 1×10¹⁸ atoms/cm³ and a diffusion depth (a depth from the surface of the semiconductor substrate 1; the same applies to the following description) of, e.g., about 1 μm. The N-type extension regions 22 have an impurity concentration of, e.g., about 1×10¹⁸ to 5×10²¹ atoms/cm³ and a diffusion depth of, e.g., about 10 nm. The N-type source/drain regions 23 have an impurity concentration of, e.g., about 1×10¹⁸ to 1×10²² atoms/cm³ and a diffusion depth of, e.g., about 25 to 50 nm.

The semiconductor device according to the present embodiment described above has the following advantage. The N-type impurity region 28 is formed in the portion of the active region 50a which is located below the gate insulating film 13a and which contacts the element isolation region 32. Thus, even if a part of the gate insulating film 13a on the active region 50a, which is located close to the element isolation region 32, is negatively charged due to the reaction between oxygen diffused from the element isolation region 32 and the high-k insulating film 12a, and holes are induced in the surface of the active region 50a, the induced holes are neutralized due to the N-type impurity region 28. That is, since the N-type impurity region 28, i.e., the impurity region including electrons as majority carriers, is formed in a part of the active region 50a where the induced holes are present, the holes induced in the active region 50a can be neutralized by the electrons as majority carriers included in the N-type impurity region 28. This can prevent the threshold voltage from being locally increased due to the holes induced in the active region 50a. Thus, the threshold voltage of the N-type MIS transistor can be prevented from being increased even if the gate width is reduced with miniaturization of semiconductor devices. Since the threshold voltage of the conventional N-type MIS transistor significantly increases when the gate width (i.e., the length in the gate width direction of the active region 1a) is reduced to about 500 nm or less. Accordingly, the above advantage of the present embodiment becomes more significant as compared to the conventional semiconductor device, when the gate width is about 500 nm or less.

In the present embodiment, even if the N-type impurity region 28 is formed in the active region 50a located below the gate insulating film 13a, i.e., in the channel region, this is equivalent to the state where a negative voltage is applied to the gate electrode 16a, because the dipole is neutralized in the portion of the gate insulating film 13a which is located on the N-type impurity region 28. Accordingly, even if no voltage is applied to the gate electrode 16a, the electron density in the substrate surface portion as the N-type impurity region 28 is not high enough to render the transistor conductive. Thus, no leakage current flows in the channel region due to the N-type impurity region 28.

In the present embodiment, the N-type impurity region 28 is formed so as to surround the active region 1a. However, the above advantage of the present embodiment can be obtained if the N-type impurity region 28 is formed at least in a portion located below the gate insulating film 13a out of the portion of the active region 1a which contacts the element isolation region 32.

In the present embodiment, in order to neutralize the holes induced in the active region 50a while preventing a leakage current from flowing in the channel region due to the N-type impurity region 28, it is preferable that the impurity concentration n1 of the N-type impurity region 28 be in the range of about 1×10¹⁸ atoms/cm³ to about 1×10²⁰ atoms/cm³, both inclusive.

In the present embodiment, oxygen (a factor in neutralization of the dipole) contained in the element isolation region 32 is diffused into the high-k insulating film 12a in the range of about 10 to 40 nm from the boundary between the element isolation region 32 and the active region 1a. Thus, it is preferable that the width d1 in the gate width direction of the N-type impurity region 28 be in the range of about 10 nm to about 40 nm, both inclusive. This reliably provides the advantage described above. Since the N-type impurity region 28 is formed only in the portion of the active region 1a where the induced holes are present, the influence of the N-type impurity region 28 on transistor characteristics can be minimized.

In the present embodiment, in order to reliably obtain the above advantage of the present embodiment, specifically, in order to ensure a sufficient number of electrons enough to neutralize the holes induced in the surface of the active region 1a, it is preferable that the diffusion depth of the N-type impurity region 28 be about 20 nm or more. If the diffusion depth of the N-type impurity region 28 is too large, the number of electrons included in the N-type impurity region 28 is larger than the number of electrons required to neutralize the holes induced in the surface of the active region 1a, and a leakage current flows in the channel region due to the N-type impurity region 28. Accordingly, it is preferable that the diffusion depth of the N-type impurity region 28 be about 100 nm or less. That is, the above advantage can be reliably obtained if the diffusion depth of the N-type impurity region 28 is in the range of about 20 nm to about 100 nm, both inclusive. Since the N-type impurity region 28 is formed only near the surface of the active region 1a, the active regions 1a that adjoin each other with the element isolation region 32 interposed therebetween can be prevented from being electrically connected through the N-type impurity region 28.

In the present embodiment, the element isolation region 32 has a two-layer stacked structure of the first buried insulating film 27 as a lower layer and the second buried insulating film 31 as an upper layer. Alternatively, however, the element isolation region 32 may be formed by a single insulating film.

A manufacturing method of the semiconductor device according to the first embodiment of the present disclosure will be described below.

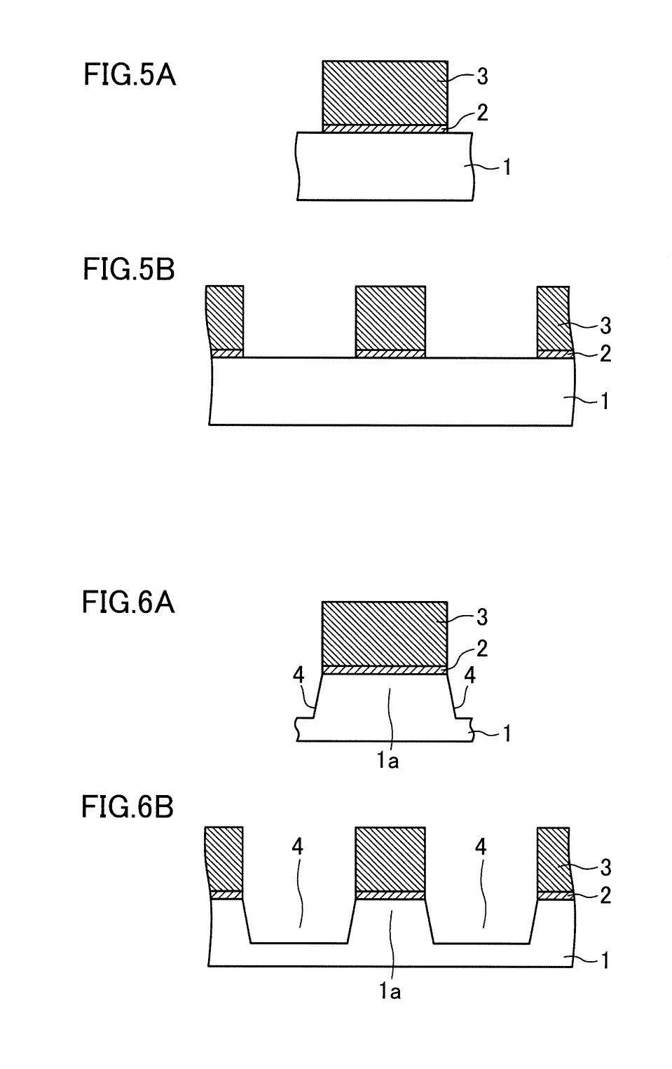

FIGS. 5A-5B, FIGS. 6A-6B, FIGS. 7A-7B, FIGS. 8A-8B, FIGS. 9A-9B, FIGS. 10A-10B, FIGS. 11A-11B, FIGS. 12A-12B, FIGS. 13A-13B, FIGS. 14A-14B, FIGS. 15A-15B, and FIGS. 16A-16B sequentially illustrate the steps of an example of the manufacturing method of the semiconductor device according to the present embodiment. FIGS. 5A, 6A, 7A, 8A, 9A, 10A, 11A, 12A, 13A, 14A, 15A, and 16A are cross-sectional views taken along the gate length direction, and FIGS. 5B, 6B, 7B, 8B, 9B, 10B, 11B, 12B, 13B, 14B, 15B, and 16B are cross-sectional views taken along the gate width direction. In FIGS. 5A-5B, FIGS. 6A-6B, FIGS. 7A-7B, FIGS. 8A-8B, FIGS. 9A-9B, FIGS. 10A-10B, FIGS. 11A-11B, FIGS. 12A-12B, FIGS. 13A-13B, FIGS. 14A-14B, FIGS. 15A-15B, and FIGS. 16A-16B, the same components as those of the semiconductor device according to the present embodiment shown in FIGS. 4A-4B are denoted by the same reference characters.

In the manufacturing method of the semiconductor device according to the present embodiment, as shown in FIGS. 5A-5B, a sacrificial oxide film 2 is first formed on a semiconductor substrate 1 such as, e.g., a silicon substrate, and then a silicon nitride film 3 as a hard mask is formed on the sacrificial oxide film 2. Thereafter, the sacrificial oxide film 2 and the silicon nitride film 3, which are formed on a region where element isolation is to be formed, are selectively removed. The thickness of the sacrificial oxide film 2 is, e.g., about 5-10 nm. The thickness of the silicon nitride film 3 is, e.g., about 50-100 nm.

Next, as shown in FIGS. 6A-6B, by using the remaining nitride film 3 as a mask, an upper part of the semiconductor substrate 1 is removed by anisotropic etching to form a trench 4. The depth of the trench 4 (the distance from the surface of the semiconductor substrate 1 to the bottom surface of the trench 4) is, e.g., about 200-300 nm. At this time, a region of the semiconductor substrate 1 which is located immediately below the remaining sacrificial oxide film 2 serves as an active region 1a. The length in the gate width direction of the active region 1a (i.e., the gate width) is, e.g., about 150 nm.

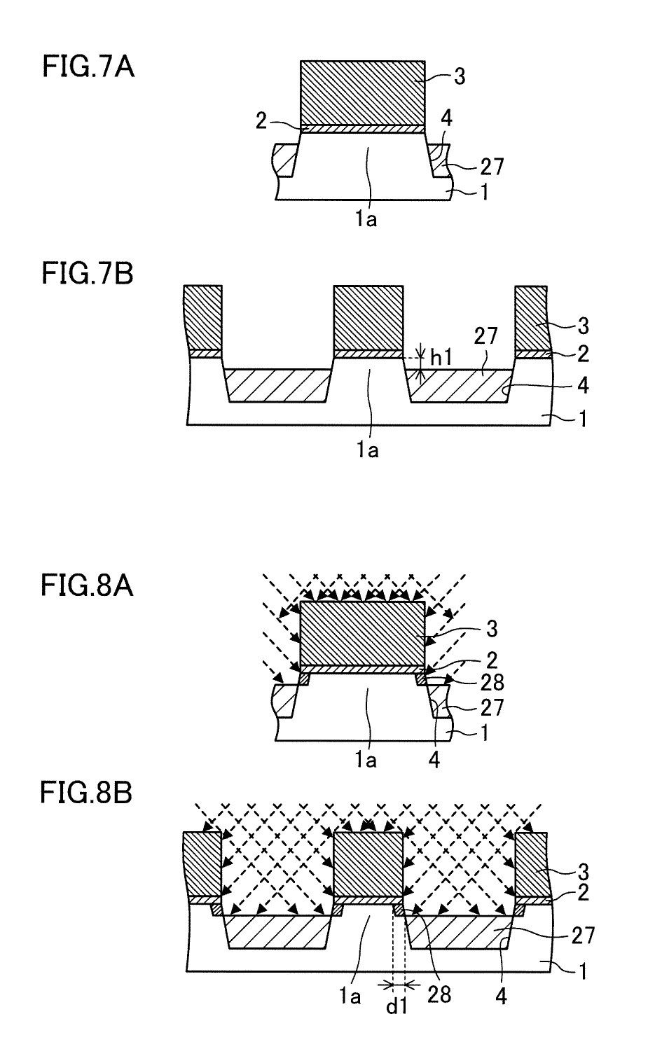

Then, as shown in FIGS. 7A-7B, a first buried insulating film 27 is formed by, e.g., a spin-on-dielectric (SOD) method so that the trench 4 is buried to an intermediate depth thereof. At this time, the distance h1 from the surface of the semiconductor substrate 1 to the surface of the first buried insulating film 27 is in the range of, e.g., 20 nm to 100 nm, both inclusive. The first buried insulating film 27 is comprised of, e.g., poly-silazane ((SiH₂NH)ₙ). Instead of the SOD method, a high density plasma chemical vapor deposition (HDP-CVD) method may be used to form the first buried insulating film 27. In this case, the first buried insulating film 27 is comprised of, e.g., a non-doped silicate glass (NSG) film.

Thereafter, as shown in FIGS. 8A-8B, by using the remaining silicon nitride film 3 as a mask, N-type impurity ions such as, e.g., arsenic (As) or antimony (Sb) are obliquely implanted (implanted at an angle with respect to a direction normal to the substrate) into the semiconductor substrate 1 to form an N-type impurity region 28 in an exposed portion of the sidewalls of the active region 1a (i.e., a portion of the active region 1a which is exposed from a region of the trench 4 located above the first buried insulating film 27). At this time, the width d1 in the gate width direction of the N-type impurity region 28 is in the range of, e.g., 10 nm to 40 nm, both inclusive. Using As or Sb as N-type impurities can suppress diffusion of these N-type impurities in a heat treatment that is performed in a later step. Thus, the relatively narrow width d1 in the gate width direction of the N-type impurity region 28, namely the width d1 in the range of 10 nm to 40 nm, both inclusive, can be maintained even after the heat treatment. Moreover, the implantation of the N-type impurities is performed at a dose of, e.g., about 5×10¹² to 5×10¹³ cm⁻² and an angle of, e.g., about 25 degrees with respect to the direction normal to the semiconductor substrate 1. In the present embodiment, the oblique implantation of the N-type impurities is performed from two directions of the gate length direction and two directions of the gate width direction, so that the N-type impurity region 28 is formed so as to surround the active region 1a (see FIG. 3).

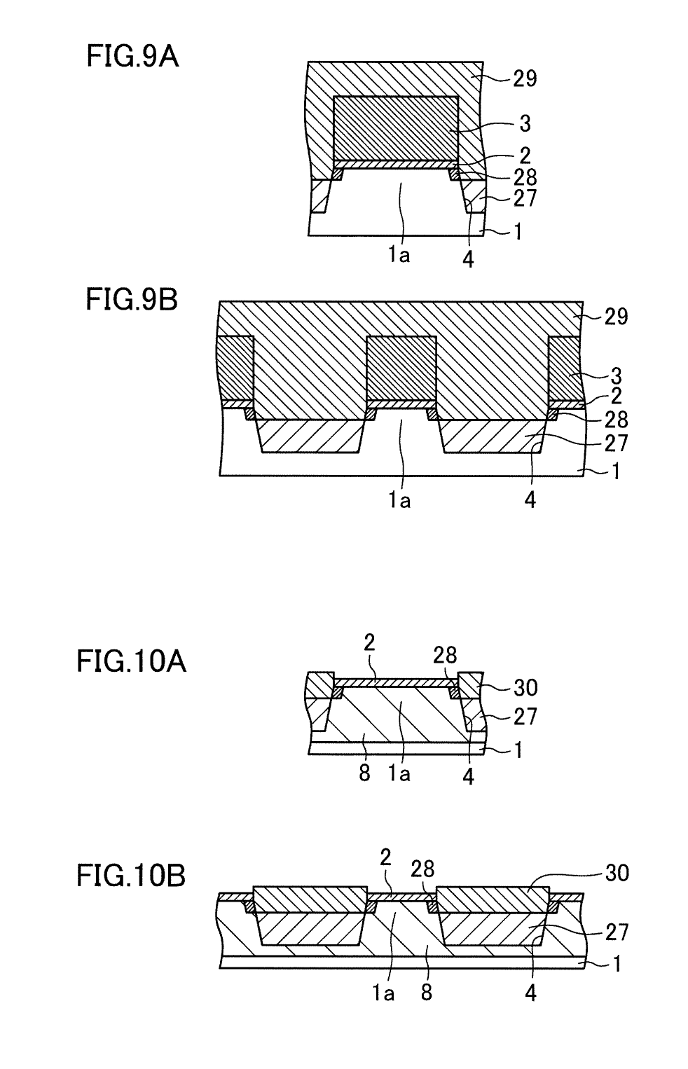

Subsequently, as shown in FIGS. 9A-9B, a second buried insulating film 29 is formed over the first buried insulating film 27 by, e.g., a HDP-CVD method so as to bury the trench 4 and the region between the remaining silicon nitride films 3. The second buried insulating film 29 is comprised of, e.g., an NSG film. Instead of the HDP-CVD method, an SOD method may be used to form the second buried insulating film 29. In this case, the second buried insulating film 29 is comprised of, e.g., poly-silazane.

Then, as shown in FIGS. 10A-10B, the silicon nitride film 3 and a part of the second buried insulating film 29 are polished by, e.g., a chemical mechanical polishing (CMP) method, and then the remaining silicon nitride film 3 is removed by wet etching using, e.g., boiled phosphoric acid. At this time, the second buried insulating film 30 remains on the first buried insulating film 27 in the trench 4. Thereafter, P-type impurities such as, e.g., boron (B) are implanted through the sacrificial oxide film 2 into a surface portion of the semiconductor substrate 1 including the active region 1a to form a P-type well region 8. This implantation of the P-type impurities is performed at energy of, e.g., 150 keV, a dose of about 2×10¹³ cm⁻², and an angle of, e.g., 0 degrees with respect to the direction normal to the semiconductor substrate 1.

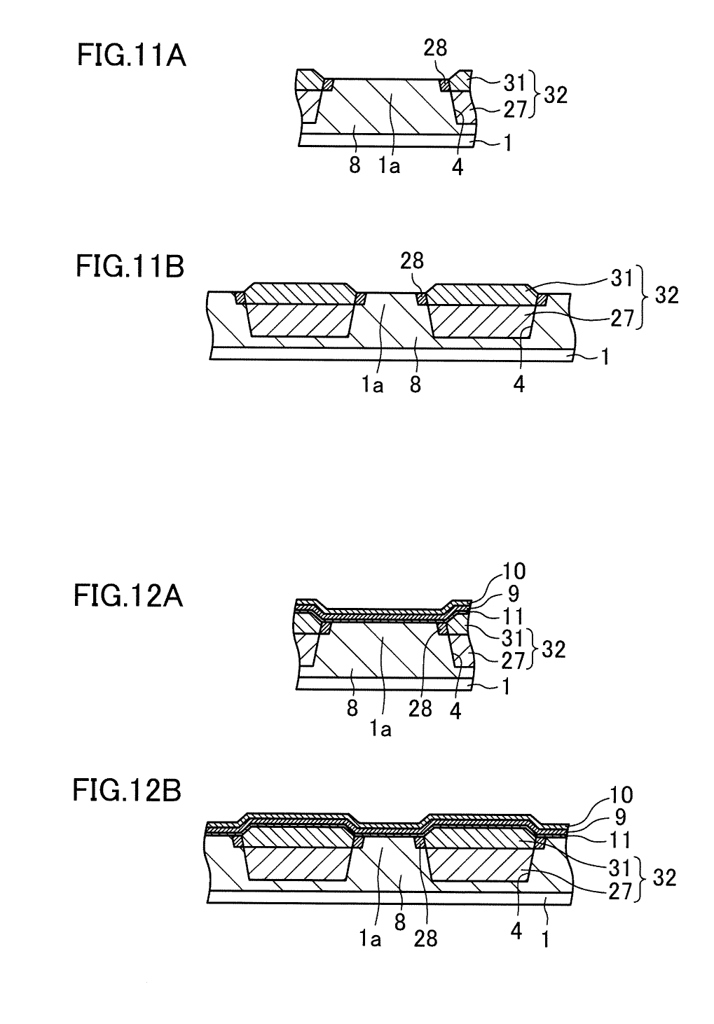

Thereafter, as shown in FIGS. 11A-11B, the sacrificial oxide film 2 is removed by wet etching using, e.g., hydrofluoric acid. At this time, a surface portion of the second buried insulating film 30 is also removed, whereby a second buried insulating film 31 is formed by the remaining second buried insulating film 30. Thus, an element isolation region 32 is formed by the first buried insulating film 27 and the second buried insulating film 31.

Subsequently, as shown in FIGS. 12A-12B, a base film 11 and a high-k insulating film 9 are sequentially formed on the active region 1a and the element isolation region 32, and then a threshold voltage adjustment metal film 10 is formed on the high-k insulating film 9. The base film 11 may be comprised of, e.g., silicon oxide (SiO₂), silicon oxynitride (SiON), etc. The high-k insulating film 9 may be comprised of, e.g., a hafnium oxide (HfSiO, HfSiON, HfO, HfON, HfZrO, HfZrON, etc.). The threshold voltage adjustment metal film 10 may be comprised of, e.g., lanthanum (La).

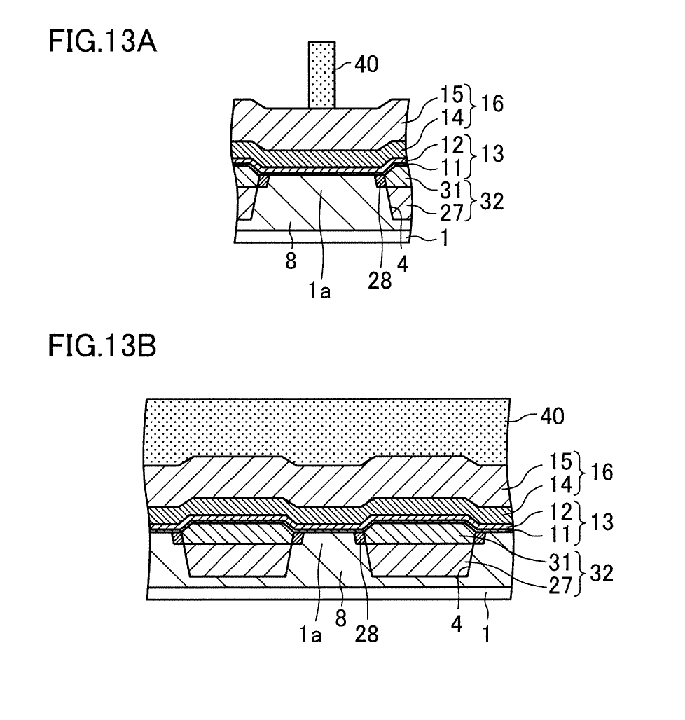

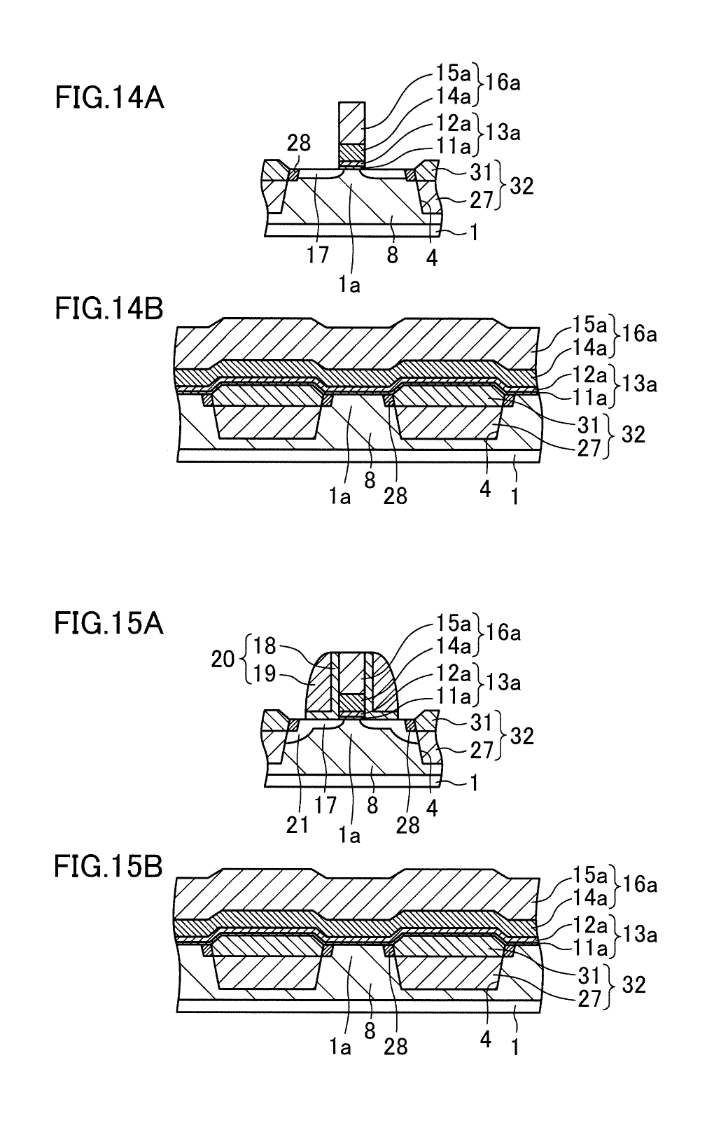

Then, as shown in FIGS. 13A-13B, a threshold voltage adjustment metal contained in the threshold voltage adjustment metal film 10 is introduced into the high-k insulating film 9 by a heat treatment. Thus, a dipole is formed in the high-k insulating film 9, and a film 13 for a gate insulating film, which has the base film 11 and the high-k insulating film 12 containing the threshold voltage adjustment metal, is formed over the semiconductor substrate 1. Thereafter, a metal-containing film 14 comprised of, e.g., titanium nitride (TiN) or tantalum nitride (TaN) is formed on the film 13 for the gate insulating film by, e.g., a CVD method. Then, a silicon film 15 comprised of, e.g., polysilicon is formed on the metal-containing film 14 by, e.g., a CVD method. Thus, a film 16 for a gate electrode, which has the metal-containing film 14 and the silicon film 15, is formed on the film 13 for the gate insulating film. Subsequently, a resist pattern 40 having a gate electrode pattern is formed on the film 16 for the gate electrode by a photolithography method. The length in the gate length direction of the resist pattern 40 is the same as the length in the gate length direction (i.e., the gate length) of the gate insulating film (see a gate insulating film 13a in FIG. 14A described below) and the gate electrode (see a gate electrode 16a in FIG. 14A described below), and is, e.g., about 32 nm.

Then, as shown in FIGS. 14A-14B, the film 16 for the gate electrode, which has the metal-containing film 14 and the silicon film 15, and the film 13 for the gate insulating film, which has the base film 11 and the high-k insulating film 12a containing the threshold voltage adjustment metal, are sequentially patterned by, e.g., dry etching by using the resist pattern 40 as a mask. Thereafter, the resist pattern 40 is removed. Thus, the gate electrode 16a having the metal-containing film 14a and the silicon film 15a is formed on the active region la and the element isolation region 32 so that the gate insulating film 13a having the base film 11a and the high-k insulating film 12a containing the threshold voltage adjustment metal is interposed therebetween. Then, N-type extension implantation regions 17 are formed on both sides of the gate electrode 16a in the active region 1a by ion implantation of N-type impurities such as, e.g., arsenic (As). This ion implantation is performed at energy of, e.g., 1.5 keV, a dose of about 1×10¹⁵ cm⁻², and an angle of, e.g., 0 degrees with respect to the direction normal to the semiconductor substrate 1.

Thereafter, a film for an inner sidewall spacer and a film for an outer sidewall spacer are sequentially formed over the entire surface of the semiconductor substrate 1 by, e.g., a CVD method. The film for the inner sidewall spacer is comprised of, e.g., silicon oxide (SiO₂), and the film for the outer sidewall spacer is comprised of, e.g., silicon nitride (SiN). Then, the film for the outer sidewall spacer and the film for the inner sidewall spacer are sequentially subjected to, e.g., anisotropic dry etching. Thus, as shown in FIGS. 15A-15B, an insulating sidewall spacer 20, which has an inner sidewall spacer 18 having an L-shaped cross section and an outer sidewall spacer 19, is formed on each side surface of the gate electrode 16a. Thereafter, ion implantation of N-type impurities such as, e.g., arsenic (As) is performed to form N-type source/drain implantation regions 21 on both sides of the insulating sidewall spacers 20 in the active region 1a. This ion implantation is performed at energy of, e.g., 10 keV, a dose of about 5×10¹⁵ cm⁻², and an angle of 0 degrees with respect to the direction normal to the semiconductor substrate 1.

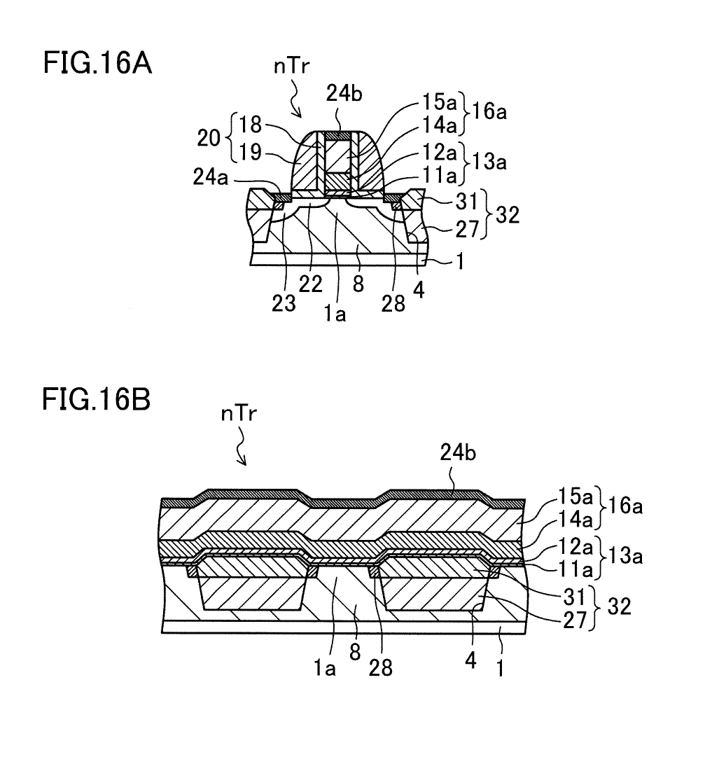

Subsequently, as shown in FIGS. 16A-16B, a heat treatment is performed at, e.g., about 900° C. to activate the N-type impurities contained in the N-type extension implantation regions 17 and the N-type impurities contained in the N-type source/drain implantation regions 21 to form N-type extension regions 22 and N-type source/drain regions 23, respectively. Then, a first silicide film 24a is formed on the N-type source/drain regions 23 (also on the N-type impurity region 28 formed at both ends in the gate length direction of the active region 1a), and a second silicide film 24b is formed on the silicon film 15a of the gate electrode 16a.

The semiconductor device according to the present embodiment shown in FIGS. 3 and 4A-4B can be manufactured in this manner.

The manufacturing method of the semiconductor device according to the present embodiment has the following advantage. The N-type impurity region 28 is formed in the portion of the active region 50a which is located below the gate insulating film 13a and which contacts the element isolation region 32. Thus, even if a part of the gate insulating film 13a on the active region 50a, which is located close to the element isolation region 32, is negatively charged due to the reaction between oxygen diffused from the element isolation region 32 and the high-k insulating film 12a, and holes are induced in the surface of the active region 50a, the induced holes are neutralized due to the N-type impurity region 28. That is, since the N-type impurity region 28, i.e., the impurity region including electrons as majority carriers, is formed in a part of the active region 50a where the induced holes are present, the holes induced in the active region 50a can be neutralized by the electrons as majority carriers included in the N-type impurity region 28. This can prevent the threshold voltage from being locally increased due to the holes induced in the active region 50a. Thus, the threshold voltage of the N-type MIS transistor can be prevented from being increased even if the gate width is reduced with miniaturization of semiconductor devices.

In the manufacturing method of the semiconductor device according to the present embodiment, the N-type impurity region 28 is formed in the portion of the active region 1a which is exposed from the region of the trench 4 located above the first buried insulating film 27 (see FIGS. 8A-8B). Thus, the N-type impurity region 28 can be formed only near the surface of the active region 1a. This can prevent the active regions 1a adjoining each other with the element isolation region 32 interposed therebetween from being electrically connected through the N-type impurity region 28. In other words, this can increase punch-through resistance. In particular, if the depth of the region of the trench 4 which is located above the first buried insulating film 27 (the distance from the surface of the semiconductor substrate 1 to the surface of the first buried insulating film 27) is in the range of 20 nm to 100 nm, both inclusive, in the step shown in FIGS. 7A-7B, the punch-through resistance can be reliably increased while preventing an increase in threshold voltage of the N-type MIS transistor.

In the manufacturing method of the semiconductor device according to the present embodiment, the oblique implantation of the N-type impurities is performed from the two directions of the gate length direction and the two directions of the gate width direction in the step shown in FIGS. 8A-8B. This can increase the flexibility of transistor layout in the case where a plurality of transistors are provided on the semiconductor substrate 1.

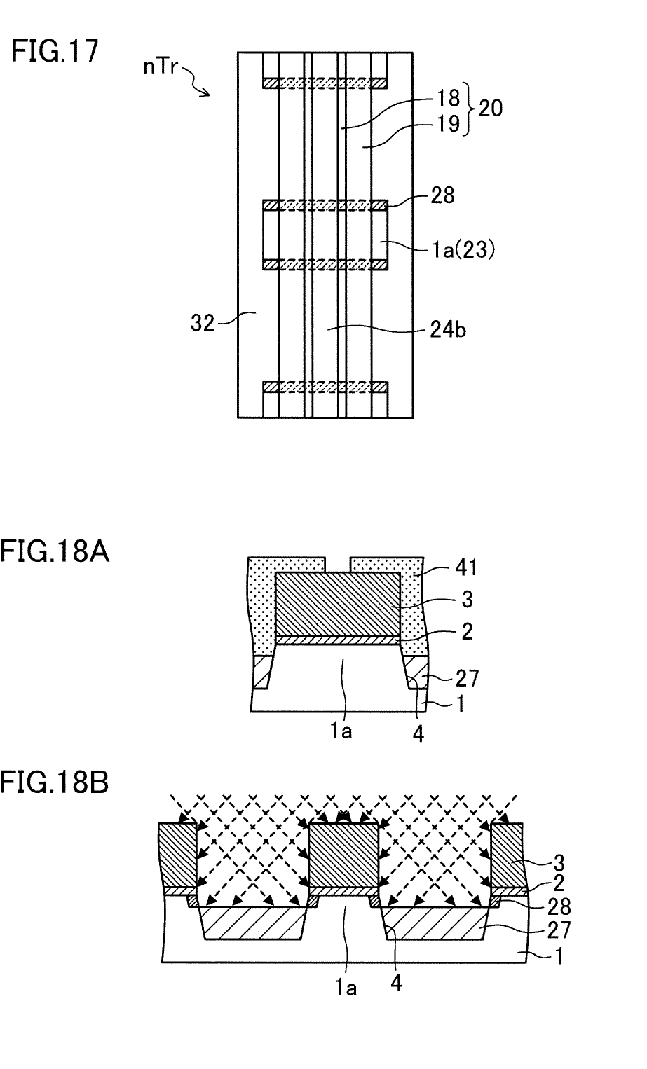

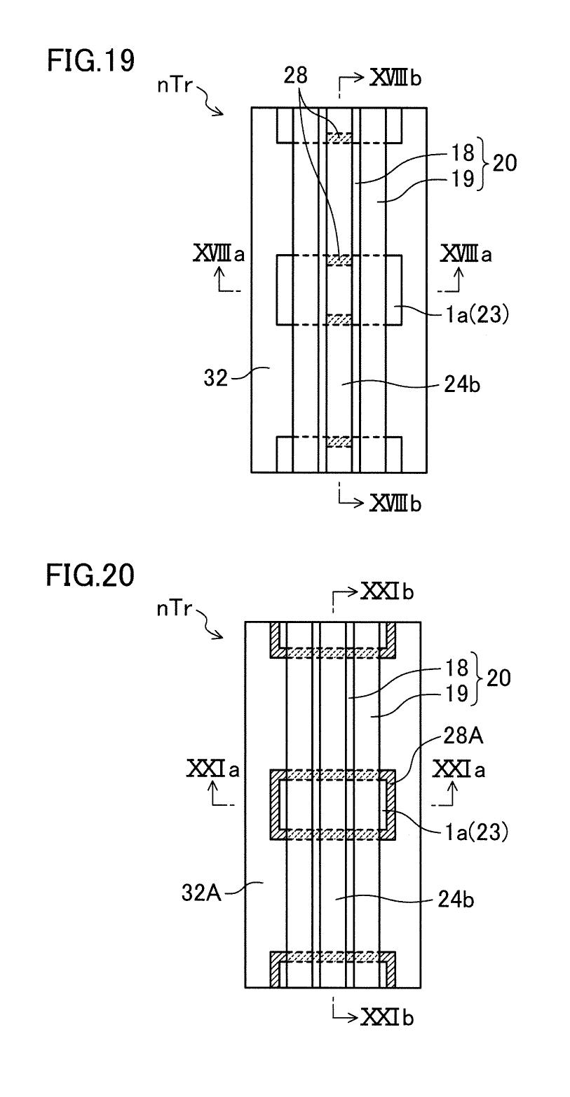

In the step shown in FIGS. 8A-8B of the manufacturing method of the semiconductor device according to the present embodiment, the oblique implantation of the N-type impurities may be performed only from the two directions of the gate width direction. In this case, as shown in FIG. 17, the N-type impurity region 28 is formed at both ends in the gate width direction of the active region 1a. This can increase throughput and can prevent an increase in threshold voltage of the N-type MIS transistor. In the case where the oblique implantation of the N-type impurities is performed only from the two directions of the gate width direction, the oblique implantation of the N-type impurities may be performed by using a resist mask 41 having an opening in a region where the gate electrode is to be formed, as shown in, e.g., FIGS. 18A-18B, instead of the step shown in FIGS. 8A-8B. In this case, as shown in FIGS. 18A-18B and FIG. 19, the N-type impurity region 28 is formed only in a portion located below the gate insulating film 13a out of the portion of the active region 1a which contacts the element isolation region 32. This can minimize the range where the N-type impurity region 28 should be formed, and thus can minimize the influence of the N-type impurity region 28 on the transistor characteristics. In FIGS. 17 and 19, the same components as those of FIG. 3 are denoted by the same reference characters. In FIGS. 18A-18B, the same components as those of FIGS. 8A-8B are denoted by the same reference characters.

### First Modification of First Embodiment

A semiconductor device according to a first modification of the first embodiment of the present disclosure will be described with reference to the drawings.

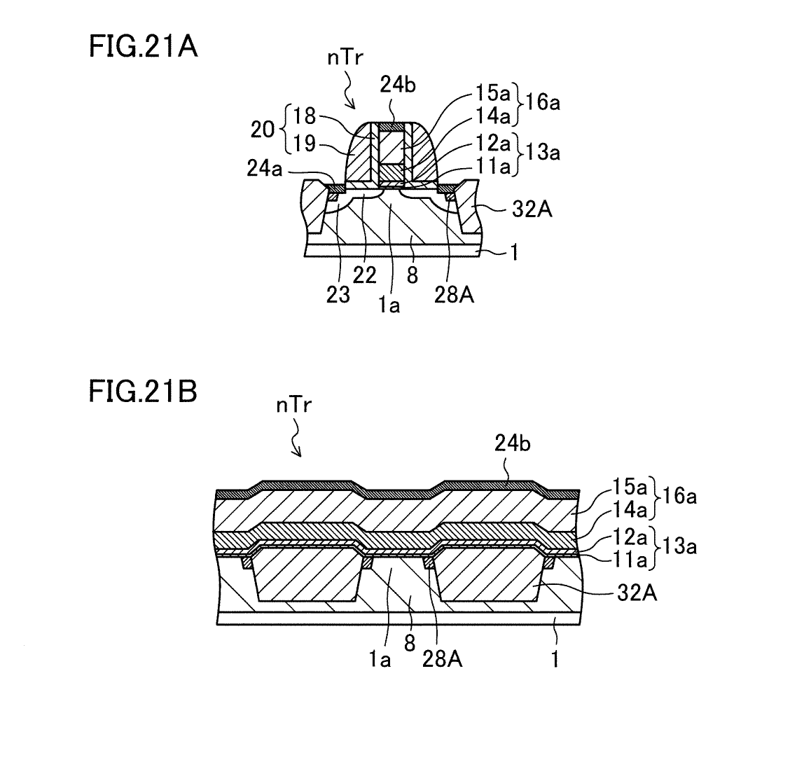

FIG. 20 is a plan view showing the configuration of the semiconductor device according to this modification. FIG. 21A is a cross-sectional view taken along the gate length direction, showing the configuration of the semiconductor device according to this modification. FIG. 21B is a cross-sectional view taken along the gate width direction, showing the configuration of the semiconductor device according to this modification. Specifically, FIGS. 21A-21B are cross-sectional views taken along lines XXIa-XXIa and XXIb-XXIb in FIG. 20, respectively. A silicide film formed on active regions (source/drain regions) is not shown in FIG. 20. In FIG. 20 and FIGS. 21A-21B, the same components as those of the semiconductor device according to the first embodiment shown in FIG. 3 and FIGS. 4A-4B are denoted with the same reference characters.

As shown in FIG. 20 and FIGS. 21A-21B, the semiconductor device of this modification is different from that of the first embodiment shown in FIG. 3 and FIGS. 4A-4B firstly in that the N-type impurity region 28 of the first embodiment is replaced with an N-type impurity region 28A, and secondly in that the element isolation region 32 of the first embodiment is replaced with an element isolation region 32A. Specifically, as described below, the N-type impurity region 28A of this modification is formed by a method different from that of the N-type impurity region 28 of the first embodiment. The element isolation region 32 of the first embodiment has a two-layer stacked structure of the first buried insulating film 27 as a lower layer and the second buried insulating film 31 as an upper layer. However, the element isolation region 32A of this modification is formed by a single insulating film.

A manufacturing method of the semiconductor device according to this modification will be described below.

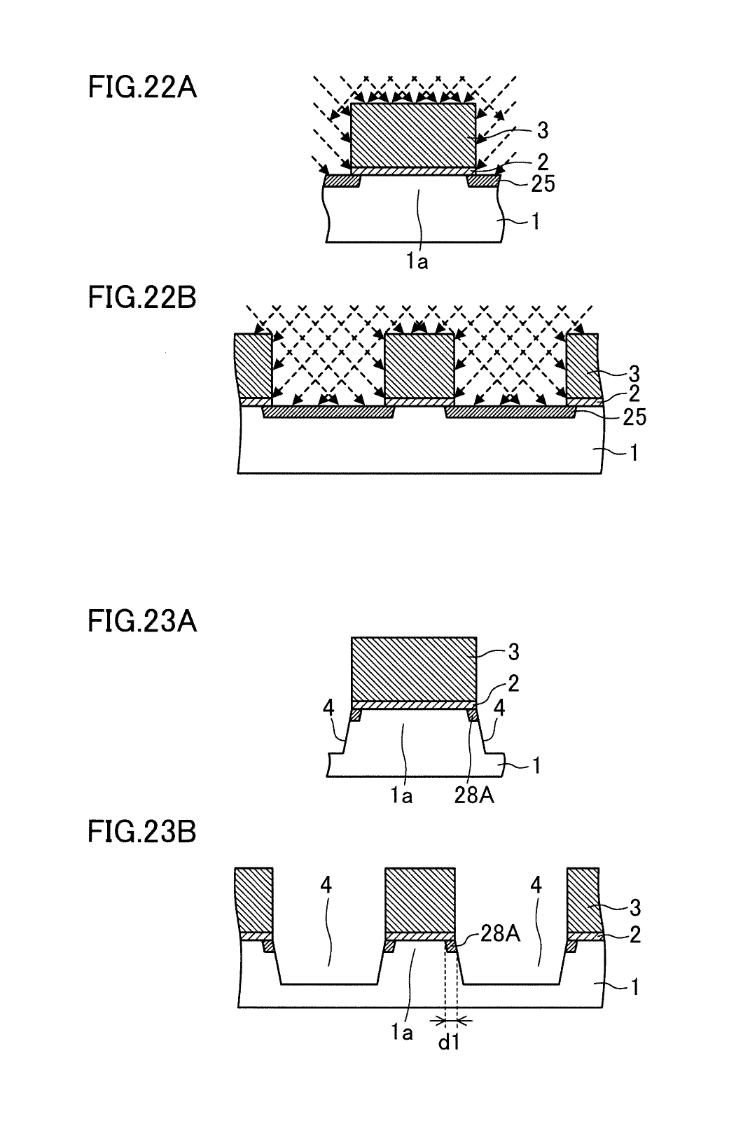

FIGS. 22A-22B, FIGS. 23A-23B, FIGS. 24A-24B, FIGS. 25A-25B, and FIGS. 26A-26B sequentially illustrate the steps of the manufacturing method of the semiconductor device according to this modification. FIGS. 22A, 23A, 24A, 25A, and 26A are cross-sectional views taken along the gate length direction, and FIGS. 22B, 23B, 24B, 25B, and 26B are cross-sectional views taken along the gate width direction. In FIGS. 22A-22B, FIGS. 23A-23B, FIGS. 24A-24B, FIGS. 25A-25B, and FIGS. 26A-26B, the same components as those of the semiconductor device according to the first embodiment shown in FIGS. 4A-4B are denoted with the same reference characters.

In the manufacturing method of the semiconductor device according to this modification, a step similar to that shown in FIGS. 5A-5B of the first embodiment is first performed.

Next, as shown in FIGS. 22A-22B, by using the remaining silicon nitride film 3 as a mask, N-type impurity ions such as, e.g., arsenic (As) or antimony (Sb) are obliquely implanted into the semiconductor substrate 1 to form an N-type impurity region 25 in an exposed portion of the semiconductor substrate 1 (a region of the surface portion of the semiconductor substrate 1 where no silicon nitride film 3 is formed). At this time, the N-type impurity region 25 is also formed in a region of the surface portion of the active region 1a which adjoins the region where no silicon nitride film 3 is formed (i.e., in a portion of the active region 1a which is located below the ends of the remaining silicon nitride film 3). The depth of the N-type impurity region 25 from the surface of the semiconductor substrate 1 is in the range of, e.g., about 20 nm to about 100 nm, both inclusive. The implantation of the N-type impurities is performed at a dose of, e.g., 5×10¹² to 5×10¹³ cm⁻² and an angle of, e.g., about 25 degrees with respect to the direction normal to the semiconductor substrate 1. In this modification, the oblique implantation of the N-type impurities may be performed from the two directions of the gate length direction and the two directions of the gate width direction.

Then, as shown in FIGS. 23A-23B, by using the remaining silicon nitride film 3 as a mask, an upper part of the semiconductor substrate 1 including the N-type impurity region 25 is removed by anisotropic etching to form a trench 4. The depth of the trench 4 (the distance from the surface of the semiconductor substrate 1 to the bottom surface of the trench 4) is, e.g., about 200-300 nm. A region of the semiconductor substrate which is located immediately below the remaining sacrificial oxide film 2 serves as an active region 1a, and a part of the N-type impurity region 25 (an N-type impurity region 28A) remains so as to surround the active region 1a. The length in the gate width direction of the active region 1a (i.e., the gate width) is, e.g., about 150 nm. The width d1 in the gate width direction of the N-type impurity region 28A is in the range of, e.g., 10 nm to 40 nm, both inclusive. As described above, in the step shown in FIGS. 22A-22B, the N-type impurity region is formed by using As or Sb as N-type impurities. This can suppress diffusion of these N-type impurities in a heat treatment that is performed in a later step. Thus, the relatively narrow width d1 in the gate width direction of the N-type impurity region 28A, namely the width d1 in the range of 10 nm to 40 nm, both inclusive, can be maintained even after the heat treatment.

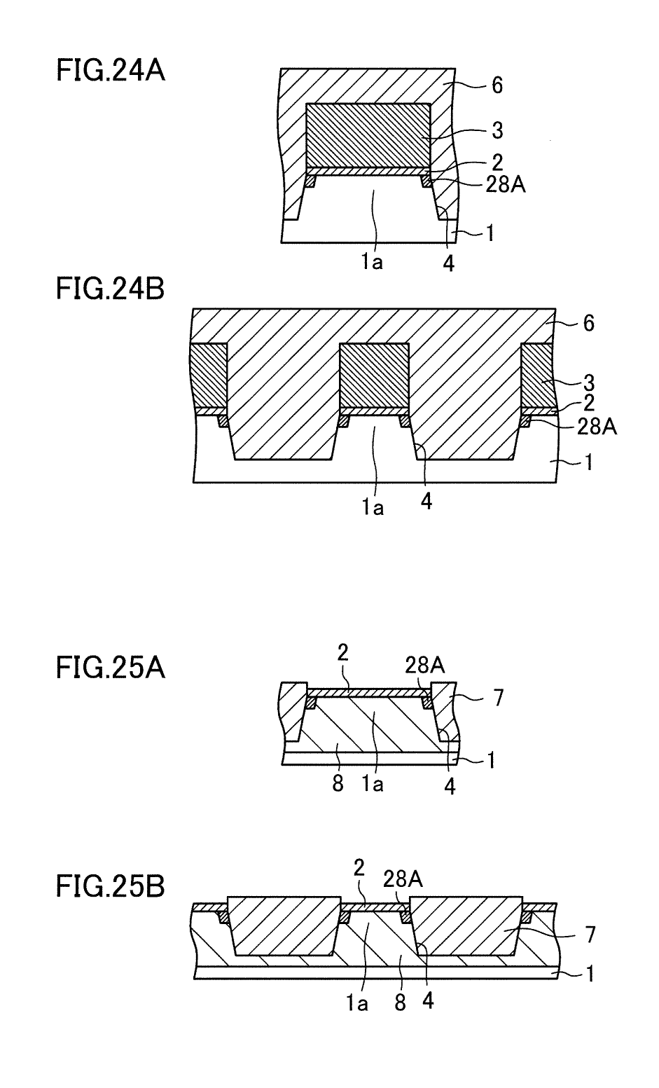

Thereafter, as shown in FIGS. 24A-24B, a buried insulating film 6 is formed by, e.g., an SOD method so as to bury the trench 4. The buried insulating film 6 is comprised of, e.g., poly-silazane. Instead of the SOD method, an HDP-CVD method may be used to form the buried insulating film 6. In this case, the buried insulating film 6 is comprised of, e.g., an NSG film.

Subsequently, as shown in FIGS. 25A-25B, the silicon nitride films 3 and a part of the buried insulating films 6 are polished by, e.g., a CMP method, and then the remaining silicon nitride film 3 is removed by wet etching using, e.g., boiled phosphoric acid. At this time, a part of the buried insulating film 6 remains in the trench 4 as a buried insulating film 7. Then, P-type impurities such as, e.g., boron (B) are implanted through the sacrificial oxide film 2 into the surface portion of the semiconductor substrate 1 including the active region 1a to form a P-type well region 8. This implantation of the P-type impurities is performed at energy of, e.g., 150 keV, a dose of about 2×10¹³ cm⁻², and an angle of, e.g., 0 degrees with respect to the direction normal to the semiconductor substrate 1.

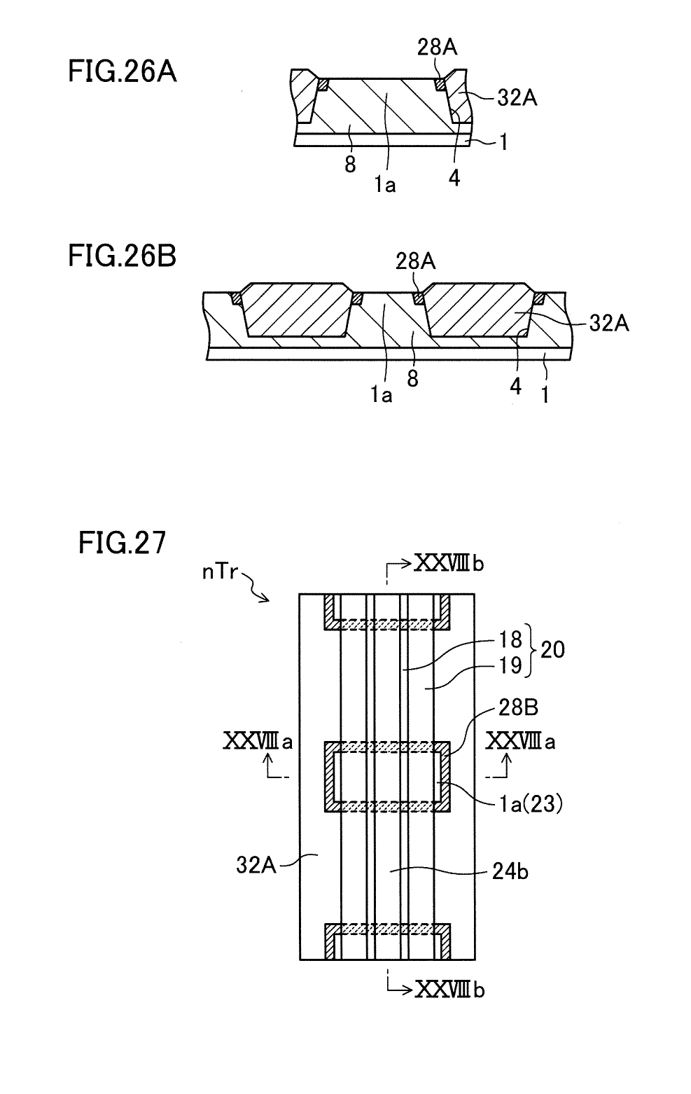

Then, as shown in FIGS. 26A-26B, the sacrificial oxide film 2 is removed by wet etching using, e.g., hydrofluoric acid. At this time, a surface portion of the buried insulating film 7 is removed, whereby an element isolation region 32A is formed.

Thereafter, steps similar to those shown in FIGS. 12A-12B, FIGS. 13A-13B, FIGS. 14A-14B, FIGS. 15A-15B, and FIGS. 16A-16B of the first embodiment are sequentially performed, whereby the semiconductor device according to this modification shown in FIG. 20 and FIGS. 21A-21B can be manufactured.

The semiconductor device according to this modification and the manufacturing method thereof has an advantage similar to that of the first embodiment described above. That is, an increase in threshold voltage of the N-type MIS transistor can be prevented even if the gate width is reduced with miniaturization of semiconductor devices.

In the manufacturing method of the semiconductor device according to this modification, N-type impurities are obliquely implanted before forming the trench 4 for forming the element isolation region. Thus, the N-type impurity region 28A can be formed only near the surface of the active region 1a. This can prevent the active regions 1a adjoining each other with the element isolation region 32A interposed therebetween from being electrically connected through the N-type impurity region 28A. In other words, this can increase punch-through resistance.

### Second Modification of First Embodiment

A semiconductor device according to a second modification of the first embodiment of the present disclosure will be described with reference to the drawings.

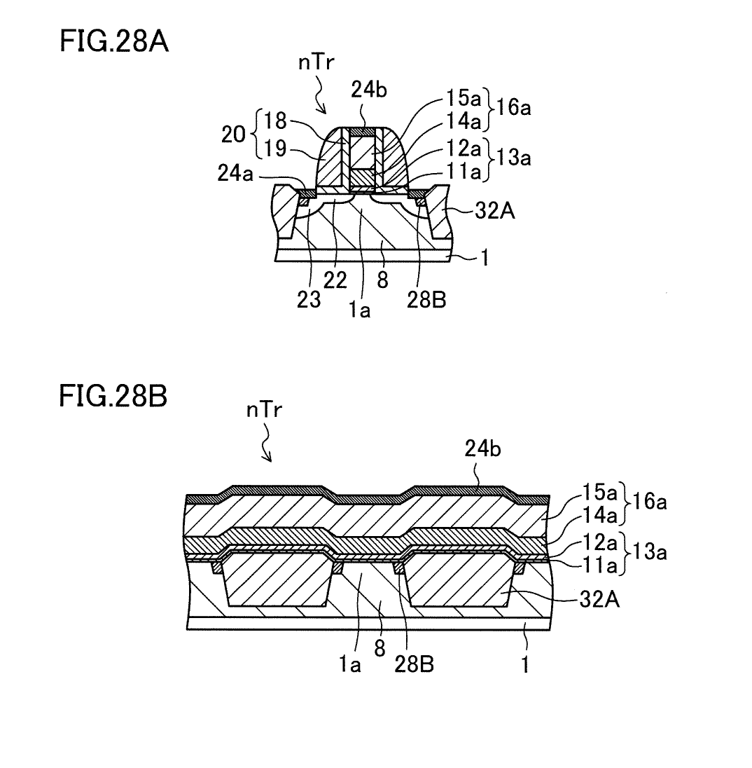

FIG. 27 is a plan view showing the configuration of the semiconductor device according to this modification. FIG. 28A is a cross-sectional view taken along the gate length direction, showing the configuration of the semiconductor device according to this modification. FIG. 28B is a cross-sectional view taken along the gate width direction, showing the configuration of the semiconductor device according to this modification. Specifically, FIGS. 28A-28B are cross-sectional views taken along lines XXVIIIa-XXVIIIa and XXVIIIb-XXVIIIb in FIG. 27, respectively. A silicide film formed on active regions (source/drain regions) is not shown in FIG. 27. In FIG. 27 and FIGS. 28A-28B, the same components as those of the semiconductor device according to the first embodiment shown in FIG. 3 and FIGS. 4A-4B are denoted with the same reference characters.

As shown in HG. 27 and FIGS. 28A-28B, the semiconductor device of this modification is different from that of the first embodiment shown in FIG. 3 and FIGS. 4A-4B firstly in that the N-type impurity region 28 of the first embodiment is replaced with an N-type impurity region 28B, and secondly in that the element isolation region 32 of the first embodiment is replaced with an element isolation region 32A. Specifically, as described below, the N-type impurity region 28B of this modification is formed by a method different from that of the N-type impurity region 28 of the first embodiment. The element isolation region 32 of the first embodiment has a two-layer stacked structure of the first buried insulating film 27 as a lower layer and the second buried insulating film 31 as an upper layer. However, the element isolation region 32A of this modification is formed by a single insulating film.

A manufacturing method of the semiconductor device according to this modification will be described below.

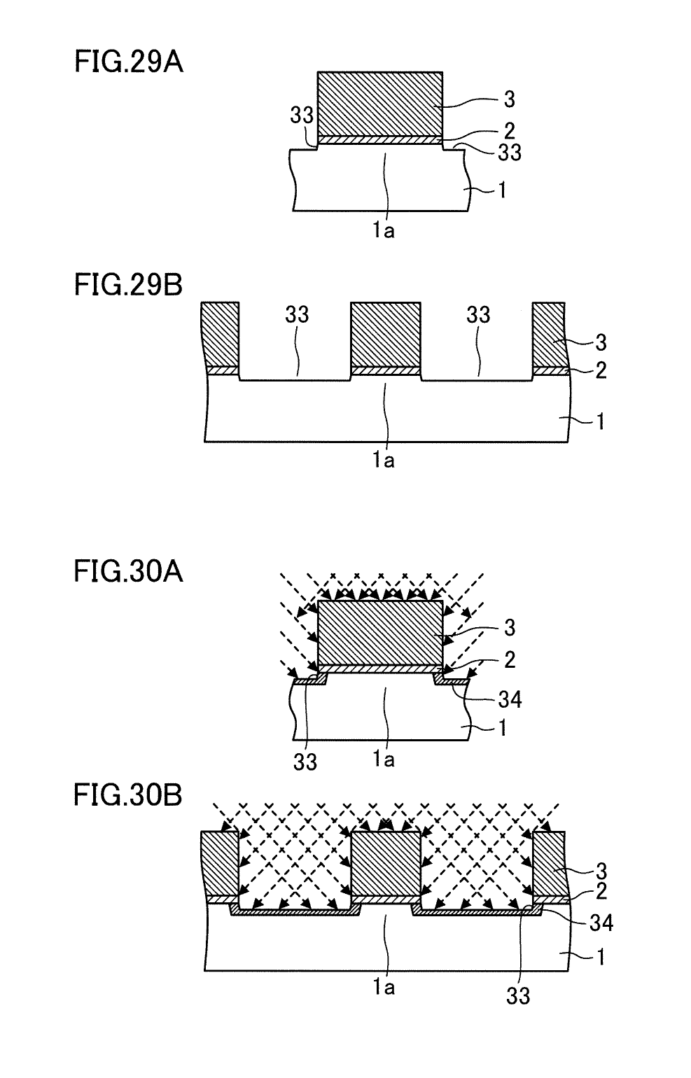

FIGS. 29A-29B, FIGS. 30A-30B, and FIGS. 31A-31B sequentially illustrate the steps of the manufacturing method of the semiconductor device according to this modification. FIGS. 29A, 30A, and 31A are cross-sectional views taken along the gate length direction, and FIGS. 29B, 30B, and 31B are cross-sectional views taken along the gate width direction. In FIGS. 29A-29B, FIGS. 30A-30B, and FIGS. 31A-31B, the same components as those of the semiconductor device according to the first embodiment shown in FIGS. 4A-4B are denoted with the same reference characters.

In the manufacturing method of the semiconductor device according to this modification, a step similar to that shown in FIGS. 5A-5B of the first embodiment is first performed.

Next, as shown in FIGS. 29A-29B, by using the remaining silicon nitride film 3 as a mask, the surface portion of the semiconductor substrate 1 is removed by anisotropic etching to form a first trench 33. The depth of the first trench 33 (the distance from the surface of the semiconductor substrate 1 to the bottom surface of the first trench 33) is in the range of, e.g., about 20 nm to about 100 nm, both inclusive. A region of the semiconductor substrate 1 which is located immediately below the remaining sacrificial oxide film 2 serves as an active region 1a. The length in the gate width direction of the active region 1a (i.e., the gate width) is, e.g., about 150 nm.

Then, as shown in FIGS. 30A-30B, by using the remaining silicon nitride film 3 as a mask, N-type impurity ions such as, e.g., arsenic (As) or antimony (Sb) are obliquely implanted into the semiconductor substrate 1 to form an N-type impurity region 34 in an exposed portion of the semiconductor substrate 1 (i.e., in the surface portion of the semiconductor substrate 1 which serves as the bottom of the first trench 33). At this time, the N-type impurity region 34 is also formed in the active region 1a that serves as the sidewall portions of the first trench 33 (i.e., in a region of the surface portion of the active region 1a which is located below the ends of the remaining silicon nitride film 3). The oblique implantation of the N-type impurities is performed at a dose of, e.g., about 5×10¹² to 5×10¹³ cm⁻² and an angle of, e.g., about 25 degrees with respect to the direction normal to the semiconductor substrate 1. In this modification, the oblique implantation of the N-type impurities may be performed from the two directions of the gate length direction and the two directions of the gate width direction.

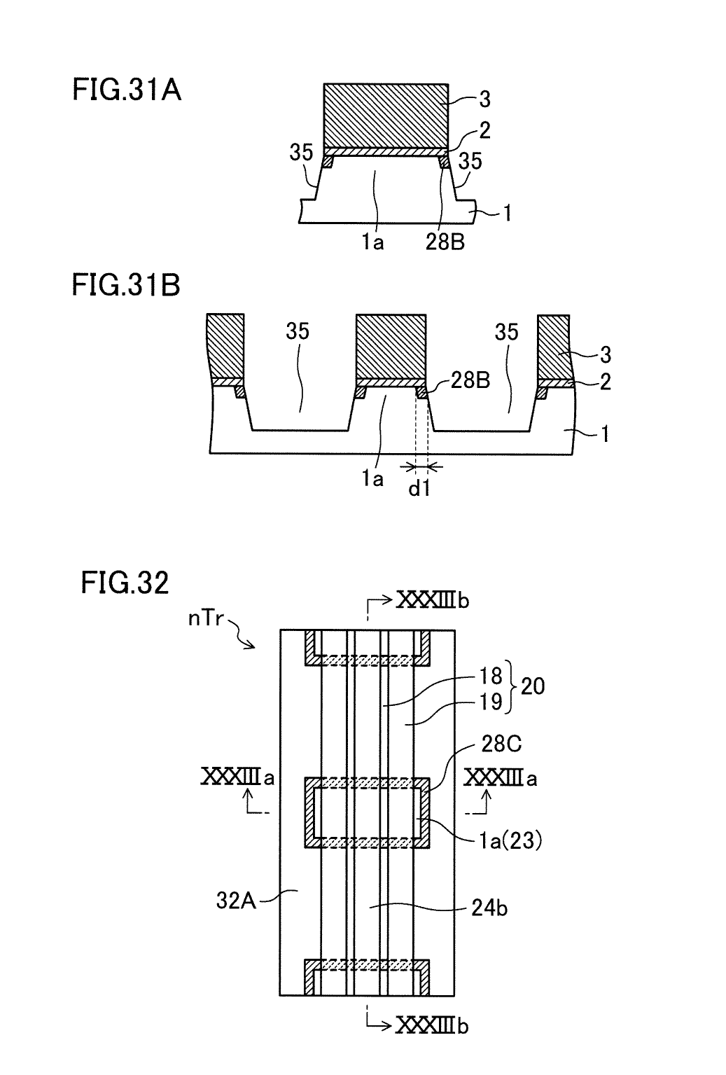

Thereafter, as shown in FIGS. 31A-31B, by using the remaining silicon nitride film 3 as a mask, a region of the upper part of the semiconductor substrate 1 (including the N-type impurity region 34), which is located below the first trench 33, is removed by anisotropic etching to form a second trench 35. The depth of the second trench 35 (the distance from the surface of the semiconductor substrate 1 to the bottom surface of the second trench 35) is, e.g., about 200-300 nm. The second trench 35 corresponds to the trench 4 of the first embodiment and the first modification thereof. By forming the second trench 35, a part of the N-type impurity region 34 (an N-type impurity region 28B) remains so as to surround the active region 1a. The width d1 in the gate width direction of the N-type impurity region 28B is in the range of, e.g., 10 nm to 40 nm, both inclusive. As described above, in the step shown in FIGS. 30A-30B, the N-type impurity region is formed by using As or Sb as N-type impurities. This can suppress diffusion of these N-type impurities in a heat treatment that is performed in a later step. Thus, the relatively narrow width d1 in the gate width direction of the N-type impurity region 28B, namely the width d1 in the range of 10 nm to 40 nm, both inclusive, can be maintained even after the heat treatment.

Then, steps similar to those shown in FIGS. 24A-24B, FIGS. 25A-25B, and FIGS. 26A-26B of the first modification of the first embodiment and steps similar to those shown in FIGS. 12A-12B, FIGS. 13A-13B, FIGS. 14A-14B, FIGS. 15A-15B, and FIGS. 16A-16B of the first embodiment are sequentially performed, whereby the semiconductor device according to this modification shown in FIG. 27 and FIGS. 28A-28B can be manufactured.

The semiconductor device according to this modification and the manufacturing method thereof has an advantage similar to that of the first embodiment described above. That is, an increase in threshold voltage of the N-type MIS transistor can be prevented even if the gate width is reduced with miniaturization of semiconductor devices.

According to the manufacturing method of the semiconductor device of this modification, the N-type impurity region 28B is formed in the portion of the active region 1a which serves as the sidewall portions of the shallow first trench 33. Thus, the N-type impurity region 28B can be formed only near the surface of the active region 1a. This can prevent the active regions 1a adjoining each other with the element isolation region 32A interposed therebetween from being electrically connected through the N-type impurity region 28B. In other words, this can increase punch-through resistance. In particular, if the depth of the first trench 33 (the distance from the surface of the semiconductor substrate 1 to the bottom surface of the first trench 33) is in the range of 20 nm to 100 nm, both inclusive, in the step shown in FIGS. 29A-29B, the punch-through resistance can be reliably increased while preventing an increase in threshold voltage of the N-type MIS transistor.

### Third Modification of First Embodiment

A semiconductor device according to a third modification of the first embodiment of the present disclosure will be described below with reference to the drawings.

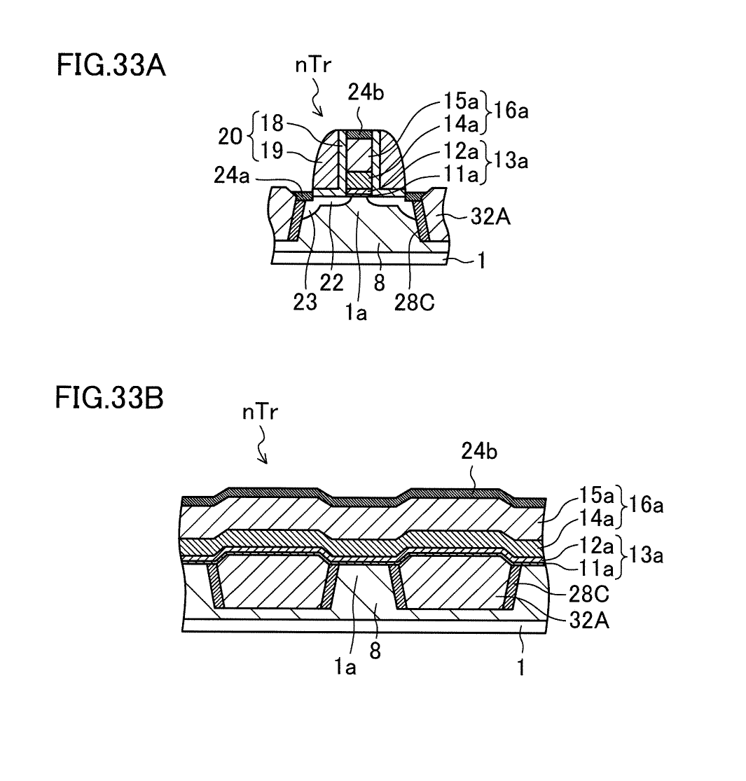

FIG. 32 is a plan view showing the configuration of the semiconductor device according to this modification. FIG. 33A is a cross-sectional view taken along the gate length direction, showing the configuration of the semiconductor device according to this modification. FIG. 33B is a cross-sectional view taken along the gate width direction, showing the configuration of the semiconductor device according to this modification. Specifically, FIGS. 33A-33B are cross-sectional views taken along lines XXXIIIa-XXXIIIa and XXXIIIb-XXXIIIb in FIG. 32, respectively. A silicide film formed on active regions (source/drain regions) is not shown in FIG. 32. In FIG. 32 and FIGS. 33A-33B, the same components as those of the semiconductor device according to the first embodiment shown in FIG. 3 and FIGS. 4A-4B are denoted with the same reference characters.

As shown in FIG. 32 and FIGS. 33A-33B, the semiconductor device of this modification is different from that of the first embodiment shown in FIG. 3 and FIGS. 4A-4B firstly in that the N-type impurity region 28 of the first embodiment is replaced with an N-type impurity region 28C, and secondly in that the element isolation region 32 of the first embodiment is replaced with an element isolation region 32A. Specifically, the N-type impurity region 28 of the first embodiment is formed to extend to a shallower depth in the semiconductor substrate 1 than the N-type source/drain regions 23. However, as described below, the N-type impurity region 28C of this modification is formed to extend to a greater depth in the semiconductor substrate 1 than the N-type source/drain regions 23 by using a method different from that of the N-type impurity region 28 of the first embodiment. The element isolation region 32 of the first embodiment has a two-layer stacked structure of the first buried insulating film 27 as a lower layer and the second buried insulating film 31 as an upper layer. However, the element isolation region 32A of this modification is formed by a single insulating film.

A manufacturing method of the semiconductor device according to this modification will be described below.

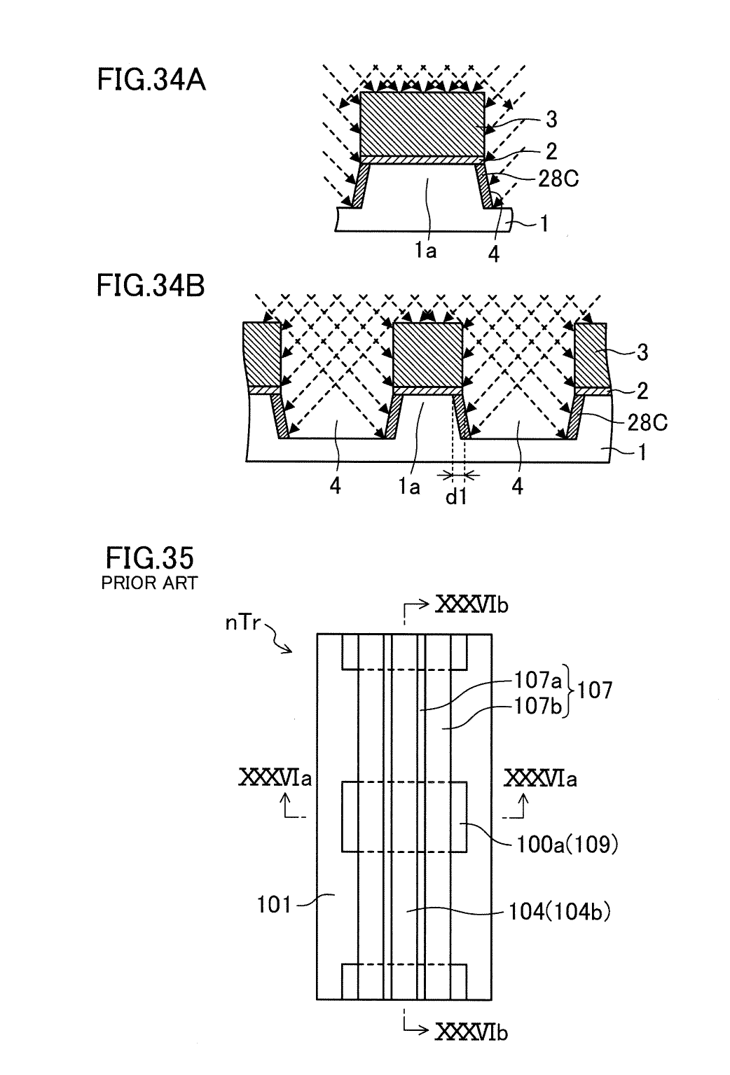

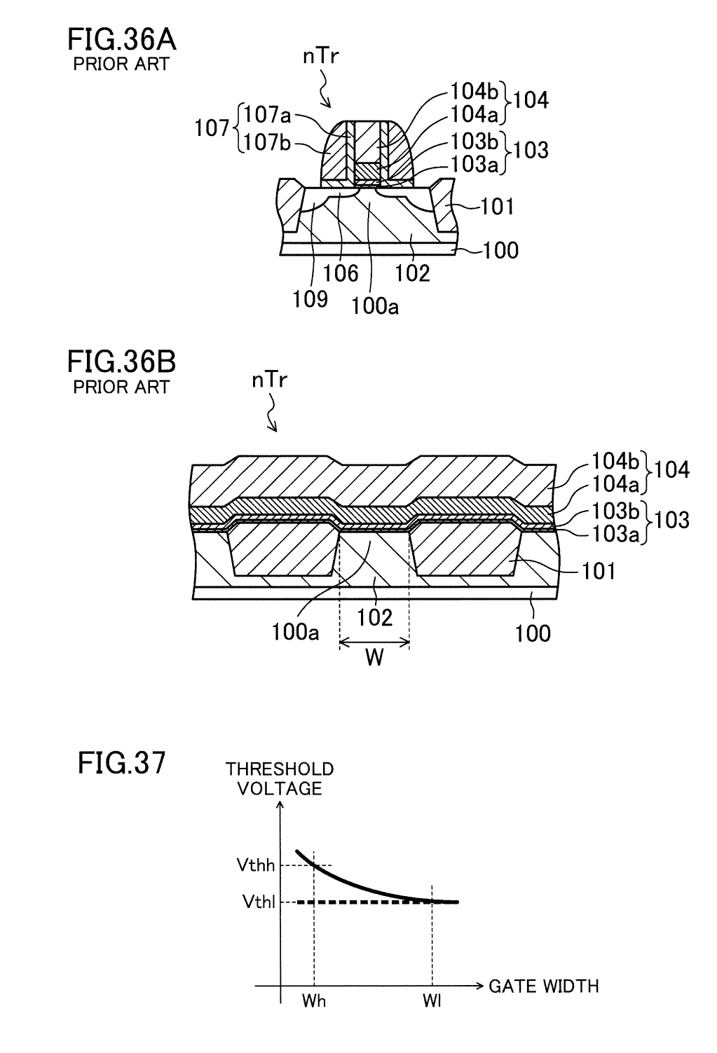

FIGS. 34A-34B illustrate a step of the manufacturing method of the semiconductor device according to this modification. FIGS. 34A is a cross-sectional view taken along the gate length direction, and FIG. 34B is a cross-sectional view taken along the gate width direction. In FIGS. 34A-34B, the same components as those of the semiconductor device according to the first embodiment shown in FIGS. 4A-4B are denoted with the same reference characters.

In the manufacturing method of the semiconductor device according to this modification, steps similar to those shown in FIGS. 5A-5B and FIGS. 6A-6B of the first embodiment are first sequentially performed.

Next, as shown in FIGS. 34A-34B, by using the remaining silicon nitride film 3 as a mask, N-type impurity ions such as, e.g., arsenic (As) or antimony (Sb) are obliquely implanted into the semiconductor substrate 1 to form an N-type impurity region 28C in a portion of the active region 1a which serves as the sidewall portions of the trench 4. At this time, the width d1 in the gate width direction of the N-type impurity region 28C is in the range of, e.g., 10 nm to 40 nm, both inclusive. Using As or Sb as the N-type impurities can suppress diffusion of these N-type impurities in a heat treatment that is performed in a later step. Thus, the relatively narrow width d1 in the gate width direction of the N-type impurity region 28C, namely the width d1 in the range of 10 nm to 40 nm, both inclusive, can be maintained even after the heat treatment. The implantation of the N-type impurities is performed at a dose of, e.g., about 5×10¹² to 5×10¹³ cm ⁻² and an angle of, e.g., about 25 degrees with respect to the direction normal to the semiconductor substrate 1. In this modification, the oblique implantation of the N-type impurities may be performed from the two directions of the gate length direction and the two directions of the gate width direction.

Then, steps similar to those shown in FIGS. 24A-24B, FIGS. 25A-25B, and FIGS. 26A-26B of the first modification of the first embodiment and steps similar to those shown in FIGS. 12A-12B, FIGS. 13A-13B, FIGS. 14A-14B, FIGS. 15A-15B, and FIGS. 16A-16B of the first embodiment are sequentially performed, whereby the semiconductor device according to this modification shown in FIG. 32 and FIGS. 33A-33B can be manufactured.

The semiconductor device according to this modification and the manufacturing method thereof has an advantage similar to that of the first embodiment described above. That is, an increase in threshold voltage of the N-type MIS transistor can be prevented even if the gate width is reduced with miniaturization of semiconductor devices.

In the step shown in FIGS. 34A-34B of this modification The N-type impurity region 28C is formed in the portion of the active region 1a which serves as the sidewall portions of the trench 4. However, the N-type impurity region 28C need only be formed at least in an upper part of the active region 1a which serves as the sidewall portions of the trench 4 (e.g., in a portion of the active region 1a which extends to a depth of about 20 nm or more from the surface of the semiconductor substrate 1). In particular, in order to increase punch-through resistance, it is preferable to adjust the implantation angle for the implantation of the n-type impurities so that the N-type impurity region 28C is formed in a portion extending to a depth of about 100 nm from the surface of the semiconductor substrate 1 out of the portion of the active region 1a which serves as the sidewall portions of the trench 4.

In the first embodiment and each of the modifications thereof, the high-k insulating film 12a forming the gate insulating film 13a contains La as a threshold voltage adjustment metal. Alternatively, however, the high-k insulating film 12a may contain other lanthanoid element, magnesium (Mg), etc.

In the first embodiment and each of the modifications thereof, the base film 11a comprised of silicon oxide is interposed between the high-k insulating film 12a forming the gate insulating film 13a and the active region 1a. However, a base film comprised of, e.g., silicon oxynitride (SiON) etc. may be interposed between the high-k insulating film 12a and the active region 1a. Alternatively, a base film may not be interposed between the high-k insulating film 12a and the active region 1a.

In the first embodiment and each of the modifications thereof, the gate electrode 16a has the metal-containing film 14a formed on the gate insulating film 13a, and the silicon film 15a formed on the metal-containing film 14a. However, it should be understood that the configuration of the gate electrode 16a is not specifically limited to this.

Although the semiconductor device including the N-type MIS transistor nTr is described as a specific example in the first embodiment and each of the modifications thereof, the present disclosure is not limited to this, and may be applied to, e.g., an N-type MIS transistor in a semiconductor device including an N-type MIS transistor and a P-type MIS transistor.

What is claimed is:

1. A semiconductor device, comprising:
an N-type MIS transistor, wherein
the N-type MIS transistor includes
an active region surrounded by an element isolation region in a semiconductor substrate,
a gate insulating film formed on the active region and the element isolation region and having a high-k insulating film,
a gate electrode formed on the gate insulating film,
N-type source/drain regions formed on both sides of the gate electrode in the active region, and
an N-type impurity region formed at least in a portion located below the gate insulating film out of a portion of the active region which contacts the element isolation region.

2. The semiconductor device of claim 1, wherein
the N-type impurity region is formed at both ends in a gate width direction of the active region.

3. The semiconductor device of claim 1, wherein
the N-type impurity region is formed so as to surround the active region.

4. The semiconductor device of claim 1, wherein
the element isolation region has a two-layer structure.

5. The semiconductor device of claim 4, wherein
a lower surface of the N-type impurity region is located at a same depth as or a greater depth than a lower surface of an upper layer portion of the element isolation region.

6. The semiconductor device of claim 1, wherein
the element isolation region is formed by a single insulating film.

7. The semiconductor device of claim 1, wherein
the N-type impurity region is formed to extend to a shallower depth than the N-type source/drain regions.

8. The semiconductor device of claim 1, wherein
the N-type impurity region is formed to extend to a greater depth than the N-type source/drain regions.

9. The semiconductor device of claim 1, wherein
the N-type impurity region has an impurity concentration in a range of 1×10¹⁸ atoms/cm³ to 1×10²⁰ atoms/cm³, both inclusive.

10. The semiconductor device of claim 1, wherein
the N-type impurity region has a length in a range of 10 nm to 40 nm, both inclusive, in a gate width direction.

11. The semiconductor device of claim 1, wherein
the N-type impurity region has a depth in a range of 20 nm to 100 nm, both inclusive, from a surface of the semiconductor substrate.

12. The semiconductor device of claim 1, wherein
the active region has a length of 500 nm or less in a gate width direction.

13. The semiconductor device of claim 1, wherein
the N-type impurity region contains arsenic or antimony.

14. The semiconductor device of claim 1, wherein
the gate insulating film further has a base film formed below the high-k insulating film.

15. The semiconductor device of claim 1, wherein
the high-k insulating film contains a threshold voltage adjustment metal.

16. The semiconductor device of claim 15, wherein
the threshold voltage adjustment metal is lanthanum.

17. The semiconductor device of claim 1, wherein
the gate electrode has a metal-containing film formed on the gate insulating film, and a silicon film formed on the metal-containing film.
